(19) United States
(12) Patent Application Publication
(10) Pub. No.: US 2023/0151179 A1
(43) Pub. Date: May 18, 2023

(54) HOLLOW MICROBALLOONS FOR CMP POLISHING PAD

(71) Applicant: TOKUYAMA CORPORATION, Shunan-shi, Yamaguchi (JP)

(72) Inventors: Yasutomo SHIMIZU, Tsukuba-shi (JP); Takayoshi KAWASAKI, Tsukuba-shi (JP)

(73) Assignee: TOKUYAMA CORPORATION, Shunan-shi, Yamaguchi (JP)

(21) Appl. No.: 17/915,006

(22) PCT Filed: Mar. 31, 2021
(86) PCT No.: PCT/JP2021/013796

§ 371 Date: Sep. 27, 2022

(30) Foreign Application Priority Data
Mar. 31, 2020 (JP) 2020-061826

(51) Int. Cl. C08J 9/32; C08J 9/00; C08L 75/02; B24B 37/24

(52) U.S. Cl. CPC C08J 9/32; C08J 9/0061; C08L 75/02; B24B 37/24; C08J 2375/02; C08J 2423/08; C08J 2461/28; C08L 2203/14; C08L 2205/03; C08L 2205/20

(57) ABSTRACT

The hollow microballoons for CMP polishing pad of the invention are formed of at least one resin selected from the group consisting of a melamine resin, a urea resin and an amide resin and have an average particle size of 1 to 100 μm. According to the invention, there can be provided hollow microballoons for CMP polishing pad, which, when used in CMP polishing pad, exhibit excellent polishing characteristics, and can stably produce CMP polishing pad even in production of CMP polishing pad.

### TECHNICAL FIELD

The present invention relates to hollow microballoons for CMP polishing pad.

### BACKGROUND ART

Heretofore, microballoons have been used in various fields including agriculture, medicines, fragrances, liquid crystals, adhesives, electronic material parts and building materials, as microballoons encapsulating a skincare component, a fragrance component, a dye component, an analgesic component, a deodorant component, an antioxidant component, a bactericidal component, a heat storage component or the like, or as hollow microballoons that are hollow inside of the microballoons.

Recently, in particular, hollow microballoons have been investigated for the purpose of forming fine pores in polyurethane(urea)-made polishing pad for chemical mechanical polishing (CMP) of wafer polishing.

Heretofore, as hollow microballoons for CMP polishing pad, there have been known vinylidene chloride resin microballoons formed by dusting the surfaces of hollow microballoons with inorganic particles for the purpose of improving dispersibility in polyurethane(urea) resin generally used as a substrate for CMP polishing pad (PTL 1). In these, however, there is a possibility that the inorganic particles may cause wafer defects.

Therefore, the present inventors have proposed a CMP polishing pad incorporating hollow microballoons formed of a polyurethane(urea) resin in a CMP polishing pad. The polyurethane(urea) resin of the microballoons has high elasticity and good compatibility with the polyurethane(urea) resin of the substrate of the CMP polishing pad. The CMP polishing pad according to the present inventors has excellent polishing performance. (see PTL 2).

### CITATION LIST

### Patent Literature

PTL 1: JP2019-63903A
PTL 2: WO2019/198675A1

### SUMMARY OF INVENTION

### Technical Problem

In PTL 2, excellent polishing characteristics can surely be expressed by using hollow microballoons formed of a polyurethane(urea) resin. However, depending on the kind of the polymerizable monomer for the resin of CMP polishing pad, there may be concerns about solvent resistance of hollow microballoons formed of a polyurethane(urea) resin. Specifically, especially when a mixture of the hollow microballoons and the polymerizable monomer is stored for a long period of time, the polymerizable monomer may penetrate or partly dissolve in the hollow microballoons so that the hollow microballoons may deform, and consequently, there is room for improvement in stable production of desired CMP polishing pad.

Accordingly, an object of the present invention is to provide hollow microballoons which, when used in CMP polishing pad, exhibit not only excellent polishing characteristics but also excellent solvent resistance, and therefore, even in production of CMP polishing pad, can be used in stably producing CMP polishing pad.

### Solution to Problem

The present inventors have assiduously studied for the purpose of solving the above-mentioned problems and, as a result, have found that, by using hollow microballoons comprising at least one resin selected from the group consisting of a melamine resin, a urea resin and an amide resin and having an average particle size falling within a specific range, the above-mentioned problems can be solved, and have completed the present invention.

Specifically, the present invention relates to the following [1] to [9].

[1] Hollow microballoons for CMP polishing pad, comprising at least one resin selected from the group consisting of a melamine resin, a urea resin, and an amide resin and having an average particle size of 1 to 100 μm.
[2] The hollow microballoons for CMP polishing pad according to the above [1], wherein a bulk density of the hollow microballoons is 0.01 to 0.6 g/cm³.
[3] The hollow microballoons for CMP polishing pad according to any one of the above [1] to [2], wherein an ash content of the hollow microballoons is 0.5 parts by mass or less relative to 100 parts by mass of the hollow microballoons.
[4] A CMP polishing pad containing hollow microballoons for CMP polishing pad according to any one of the above [1] to [3] and a polyurethane(urea) resin.
[5] The CMP polishing pad according to the above [4], having a Shore hardness of 30A to 70D.
[6] The CMP polishing pad according to the above [4] or [5], wherein the polyurethane(urea)resin comprises a resin produced by polymerizing a polymerizable composition containing (B) a polyfunctional isocyanate compound and (CA) a compound having two or more amino groups.
[7] The CMP polishing pad according to any one of the above [4] to [6], wherein the polyurethane(urea) resin comprises a resin produced by polymerizing a polymerizable composition containing (B) a polyfunctional isocyanate compound, (CA) a compound having two or more amino groups and (CB) a compound having three or more groups of a hydroxy group and/or a thiol group.
[8] The CMP polishing pad according to the above [7], wherein a blending ratio of the (B) polyfunctional isocyanate compound, the (CA) compound having two or more amino groups, and the (CB) compound having three or more groups of a hydroxy group and/or a thiol group is 60 to 95 parts by mass, 2 to 20 parts by mass, and 1 to 30 parts by mass, respectively, relative to 100 parts by mass of the total of a component (B), a component (CA), and a component (CB).
[9] The CMP polishing pad according to any one of the above [7] to [8], wherein a (CB) compound having three or more groups of a hydroxy group and/or a thiol group comprises a polyrotaxane having three or more groups of a hydroxy group and/or a thiol group.

### Advantageous Effects of Invention

The hollow microballoons for CMP polishing pad of the present invention are hollow microballoons comprising at least one resin selected from the group consisting of a melamine resin, a urea resin and an amide resin and having an average particle size of 1 to 100 μm, and are characterized by being used in CMP polishing pad. In such use, excellent polishing characteristics can be expressed. For example, wafer defects can be reduced. Further, since the hollow microballoons have excellent solvent resistance, CMP polishing pad can be stably produced in production of CMP polishing pad.

In addition, though the hollow microballoons for CMP polishing pad of the present invention are hollow microballoons favorable for use for CMP polishing pad, these are also applicable to other various fields of thermal recording materials, agricultural chemicals, medicines, fragrances, liquid crystals, adhesives, electronic material parts, building materials and the like, in addition to the use for CMP polishing pad.

In the present specification, hollow microballoons for CMP polishing pad may be simply referred to as hollow microballoons.

### DESCRIPTION OF EMBODIMENTS

In the hollow microballoons for CMP polishing pad of the present invention, the resin that forms the hollow microballoons is at least one resin selected from the group consisting of a melamine resin, a urea resin and an amide resin.

Above all, a preferred resin in the present invention is a melamine resin.

In the present invention, the melamine resin is a resin in which the main chain is formed by polycondensation of a polyfunctional amine containing melamine and a formaldehyde, the urea resin is a resin in which the main chain is formed by polycondensation of a urea (optionally further containing a polyfunctional amine) and a formaldehyde, and the amide resin is a resin having an amide bond in the main chain.

The average particle size of the hollow microballoons for CMP polishing pad of the present invention is 1 to 100 μm. Falling within the range, the hollow microballoons can express excellent polishing characteristics when incorporated in CMP polishing pad. Further, the average particle size of the hollow microballoons is preferably 5 to 80 μm, more preferably 10 to 50 μm.

For measurement of the average particle size of the hollow microballoons, a known method is employable. Specifically, an image analysis method is employable. Using an image analysis method, the particle size can be measured easily. The average particle size is an average particle size of primary particles. For measurement of the average particle size according to an image analysis method, for example, a scanning electron microscope (SEM) can be used. For example, using SEM, the particle size of 100 hollow microballoons is measured, and the found data are averaged to give an average particle size.

The bulk density of the hollow microballoons for CMP polishing pad of the present invention is, though not specifically limited, preferably 0.01 to 0.6 g/cm³, more preferably 0.02 to 0.4 g/cm³. Within the range, optimum fine pores can be formed on the polishing surface of CMP polishing pad.

The ash content of the hollow microballoons for CMP polishing pad of the present invention is, though not specifically limited, preferably 0.5 parts by mass or less per 100 parts by mass of the hollow microballoons, as measured according to the method described in the section of Examples to be given below, more preferably 0.3 parts by mass or less, even more preferably 0.1 parts by mass or less, and is most preferably unmeasurable. Within the range, when the microballoons are used in CMP polishing pad, wafer defects can be reduced.

As described above, the hollow microballoons for CMP polishing pad of the present invention comprise at least one resin selected from the group consisting of a melamine resin, a urea resin and an amide resin. In general, these resins are produced by polymerizing the polymerizable monomers shown below.

In the present invention, the polymerizable monomers to constitute these resins are mentioned below.

In the case where the hollow microballoons for CMP polishing pad are formed of a melamine resin, a melamine and a formaldehyde and optionally any other polyfunctional amine may be used as the polymerizable monomer, and above all, a melamine formaldehyde prepolymer compound is preferred.

The melamine formaldehyde prepolymer compound is a melamine-formaldehyde precondensation product of melamine and formaldehyde, and can be produced according to an ordinary method. Examples of the melamine-formaldehyde precondensation product of melamine and formaldehyde include methylolmelamine. As the melamine formaldehyde prepolymer compound, commercial products can be appropriately used. For example, the commercial products include Beckamine APM, Beckamine M-3, Beckamine M-3 (60), Beckamine MA-S, Beckamine J-101, Beckamine J-1 01LF (by DIC Corporation), Nikaresin S-176, Nikaresin S-260 (by Nippon Carbide Industries Co., Inc.), and Mirbane Resin SM-800 (by Showa Denko K.K.).

In the case where the hollow microballoons for CMP polishing pad are formed of a urea resin, a urea and a formaldehyde and optionally any other polyfunctional amine may be used as the polymerizable monomer, and above all, a urea formaldehyde prepolymer compound is preferred.

The urea formaldehyde prepolymer compound is a urea-formaldehyde precondensation product of urea and formaldehyde, and can be produced according to an ordinary method. Examples of the urea-formaldehyde precondensation product of urea and formaldehyde include methylolurea. As the urea formaldehyde prepolymer compound, commercial products can be appropriately used. For example, the commercial products include 8HSP (by Showa Denko K.K.).

In the case where the hollow microballoons for CMP polishing pad are formed of an amide resin, a polyfunctional carboxylic acid compound having at least two carboxy groups and a polyfunctional amine compound having at least two amino groups may be used as the polymerizable monomer.

The polyfunctional carboxylic acid compound having at least two carboxy groups is preferably a dicarboxylic acid compound, including a dicarboxylic acid and a dicarboxylic acid dihalide.

The dicarboxylic acid includes succinic acid, adipic acid, sebacic acid, dodecenylsuccinic acid, azelaic acid, sebacic acid, dodecanedicarboxylic acid, octadecanedicarboxylic acid, dodecenylsuccinic acid, pentadecenylsuccinic acid, octadecenylsuccinic acid, maleic acid, fumaric acid, and other alkenylenedicarboxylic acids, and decylsuccinic acid, dodecylsuccinic acid, octadecylsuccinic acid, phthalic acid, isophthalic acid, terephthalic acid, and naphthalenedicarboxylic acid.

The dicarboxylic acid dihalide includes an aliphatic dicarboxylic acid dihalide, an alicyclic dicarboxylic acid dihalide, and an aromatic dicarboxylic acid dihalide.

Examples of the aliphatic dicarboxylic acid dihalide include oxalic acid dichloride, malonic acid dichloride, succinic acid dichloride, fumaric acid dichloride, glutaric acid dichloride, adipic acid dichloride, muconic acid dichloride, sebacic acid dichloride, nonanoic acid dichloride, undecanoic acid dichloride, oxalic acid dibromide, malonic acid dibromide, succinic acid dibromide, and fumaric acid dibromide.

Examples of the alicyclic dicarboxylic acid dihalide include 1,2-cyclopropanedicarboxylic acid dichloride, 1,3-cyclobutanedicarboxylic acid dichloride, 1,3-cyclopentanedicarboxylic acid dichloride, 1,3-cyclohexanedicarboxylic acid dichloride, 1,4-cyclohexanedicarboxylic acid dichloride, 1,3-cyclopentanedicarboxylic acid dichloride, 1,2-cyclopropanedicarboxylic acid dibromide, and 1,3-cyclobutanedicarboxylic acid dibromide.

Examples of the aromatic dicarboxylic acid dihalide include phthalic acid dichloride, isophthalic acid dichloride, terephthalic acid dichloride, 1,4-naphthalenedicarboxylic acid dichloride, 1,5-(9-oxofluorene)dicarboxylic acid dichloride, 1,4-anthracenedicarboxylic acid dichloride, 1,4-anthraquinonedicarboxylic acid dichloride, 2,5-biphenyldicarboxylic acid dichloride, 1,5-biphenylenedicarboxylic acid dichloride, 4,4′-biphenyldicarbonyl dichloride, 4,4′-methylene-dibenzoic acid dichloride, 4,4′-isopropylidene-dibenzoic acid dichloride, 4,4′-bibenzyldicarboxylic acid dichloride, 4,4′-stilbenedicarboxylic dichloride, 4,4′-tolandicarboxylic acid dichloride, 4,4′-carbonyldibenzoic acid dichloride, 4,4′-oxydibenzoic acid dichloride, 4,4′-sulfonyldibenzoic acid dichloride, 4,4′-dithiodibenzoic acid dichloride, p-phenylenediacetic acid dichloride, 3,3′-p-phenylenedipropionic acid dichloride, phthalic acid dibromide, isophthalic acid dibromide, and terephthalic acid dibromide.

In the present invention, the polyfunctional carboxylic acid compound having at least two carboxy groups is preferably a dicarboxylic acid dihalide, from the viewpoint of polymerization speed.

One alone or two or more kinds of these polyfunctional carboxylic acid compounds having at least two carboxy groups can be used either singly or as combined.

The polyfunctional amine compound having at least two amino groups for use in the present invention may be any one with no limitation, so far as it has two or more amino groups in one molecule. The polyfunctional amine compound having at least two amino groups for use in the present invention is preferably a water-soluble polyamine compound.

The water-soluble polyamine compound is a compound at least partially soluble in water and having a high affinity in a hydrophilic phase than in a hydrophobic phase. For this, in general, one having a solubility at room temperature of at least 1 g/l in a hydrophilic solvent such as water can be selected. Preferably selected is a water-soluble compound having a solubility of 20 g/l or more in a hydrophilic solvent.

The water-soluble polyamine compound is a water-soluble polyfunctional amine having two or more amino groups in the molecule, and specific examples thereof include ethylenediamine, propylenediamine, 1,4-diaminobutane, hexamethylenediamine, 1,8-diaminooctane, 1,10-diaminodecane, dipropylenetriamine, bishexamethylenetriamine, tris(2-aminoethyl)amine, piperazine, 2-methylpiperazine, isophoronediamine, diethylenetriamine, triethylenetetramine, tetraethylenepentamine, hydrazine, polyethyleneimines, polyoxyalkyleneamines, polyethyleneimine, phenylenediamine (o-, m-, p-) and 4,4-diaminodiphenylmethane.

One alone or two or more kinds of these polyfunctional amine compounds having two or more amino groups can be used either singly or as combined.

Any known method is employable with no limitation for the production method for the hollow microballoons for CMP polishing pad of the present invention. For example, a polymerizable monomer to constitute a resin is formed into an emulsion of an aqueous phase and an oily phase, and thereafter polymerized according to a coacervation method, or an in-situ or interfacial polymerization method to prepare microballoons, and then the liquid inside them is removed to produce hollow microballoons, and the method is employable here. Specifically, the following method is exemplified, but the following method is not limitative. In the case where the hollow microballoons for CMP polishing pad are formed of a melamine resin or a urea resin, preferably, a water-in-oil (O/W) emulsion (hereinafter this may be referred to as O/W emulsion) is prepared and then polymerized in in-situ polymerization. Specific examples are shown below, but the production method in the present invention is not limited thereto.

The polymerization method of an O/W emulsion in the case where the hollow microballoons for CMP polishing pad are formed of a melamine resin or a urea resin is briefly divided into the following, a first step: a step of preparing (a) an oily phase containing an organic solvent (hereinafter also referred to as component (a)), a second step: a step of preparing (A) an aqueous phase containing an emulsifier (hereinafter also referred to as component (A)), a third step: a step of mixing and stirring the component (a) and the component (A) to prepare an O/W emulsion in which the aqueous phase is a continuous phase and the oily phase is a disperse phase, a fourth step: a step of adding a melamine-formaldehyde prepolymer compound (in the case of a melamine resin), or a urea-formaldehyde prepolymer (in the case of a urea resin) to the O/W emulsion to promote in-situ polymerization on the O/W emulsion interface to form a resin film to give microballoons, thereby producing a microballoon dispersion where the microballoons are dispersed, a fifth step: a step of separating the microballoons from the microballoon dispersion, and a sixth step: a step of removing the organic solvent solution from inside of the microballoons, thereby producing hollow microballoons.

### First Step:

The first step is a step of preparing the (a) oily phase containing an organic solvent, which is to be a disperse phase in the O/W emulsion.

### Second Step:

The second step is a step of preparing the (A) aqueous phase containing an emulsifier and water, which is to be a continuous phase in the O/W emulsion, optionally including a step of pH control, as needed.

This step includes a step of dissolving an emulsifier to be mentioned below in water optionally followed by pH control. For pH control, a known method is employable.

In the present invention, the amount to be used of the emulsifier is 0.01 to 20 parts by mass relative to 100 parts by mass of the aqueous phase, preferably 0.1 to 10 parts by mass. Within the range, aggregation of the liquid drops of the disperse phase in the O/W emulsion can be prevented, and microballoons having a uniform average particle size are easy to produce.

Preferably, the pH is controlled to be less than 7, more preferably within a range of 3.5 to 6.5, most preferably 4.0 to 5.5. Falling within the pH range, in-situ polymerization of a melamine-formaldehyde prepolymer (in the case of a melamine resin), or a urea-formaldehyde prepolymer (in the case of a urea resin) can be promoted.

### Third Step:

The third step is a step of mixing and stirring the component (a) prepared in the first step and the component (A) prepared in the second step to prepare an O/W emulsion in which the component (A) is a continuous phase and the component (a) is a disperse phase.

In the present invention, the method of mixing and stirring the component (a) and the component (A) to give an O/W emulsion may be a method of mixing and stirring them in consideration of the particle size of the microballoons to be produced and according to an appropriate known method. In addition, in the step of preparing the O/W emulsion, the temperature and the pH can be controlled.

In particular, a method of preparing an O/W emulsion is preferably employed, in which the component (a) and the component (A) are, after having been mixed, dispersed by stirring using a known dispersing machine of a high-speed shear mode, a friction mode, a high-pressure jet mode or an ultrasonic wave mode. Among these, a high-speed shear mode is preferred. In the case where a high-speed shear mode dispersing machine is used, the rotation number is preferably 500 to 20,000 rpm, more preferably 1,000 to 10,000 rpm. The dispersion time is preferably 0.1 to 60 minutes, more preferably 0.5 to 30 minutes. The dispersion temperature is preferably 20 to 90° C.

In the present invention, the ratio by weight of the component (a) to the component (A) is preferably such that the component (A) is 100 to 1000 parts by mass relative to 100 parts by mass of the component (a), more preferably 150 to 500 parts by mass. Within the range, a good emulsion can be produced.

### Fourth Step:

The fourth step is a step of adding a melamine-formaldehyde prepolymer compound (in the case of a melamine resin) or a urea-formaldehyde prepolymer (in the case of a urea resin) to the O/W emulsion for in-situ polymerization on the O/W emulsion interface to form a resin film to give microballoons, thereby producing a microballoon dispersion where the microballoons are dispersed.

The amount to be used of the melamine-formaldehyde prepolymer compound (in the case of a melamine resin) or the urea-formaldehyde prepolymer (in the case of a urea resin) is not specifically limited, but for forming good microballoons, the amount is preferably 0.5 to 50 parts by mass relative to 100 parts by mass of the organic solvent used in the first step, more preferably 1 to 20 parts by mass.

In the case where the melamine-formaldehyde prepolymer compound (in the case of a melamine resin) or the urea-formaldehyde prepolymer (in the case of a urea resin) is added to the O/W emulsion, the component may be directly added thereto or may be previously dissolved in water prior to addition.

In the case where the component is dissolved in water, preferably, the amount of water to be used is in a range of 50 to 10,000 parts by mass relative to 100 parts by mass of the total amount of the melamine-formaldehyde prepolymer compound (in the case of a melamine resin) or the urea-formaldehyde prepolymer (in the case of a urea resin).

The pH of the aqueous phase of a continuous phase may be controlled in the second step, or after the melamine-formaldehyde prepolymer compound (in the case of a melamine resin) or the urea-formaldehyde prepolymer (in the case of a urea resin) is added to the O/W emulsion in the fourth step, it may be controlled. The pH of the aqueous phase of a continuous phase is preferably less than 7 like in the above, more preferably the pH is controlled to be 3.5 to 6.5, and most preferably the pH is controlled to be 4.0 to 5.5. Regarding the preferred reaction temperature, the reaction is carried out preferably in a range of 40 to 90° C. The reaction time is preferably 1 to 48 hours.

### Fifth Step

The fifth step is a step of separating the microballoons from the microballoon dispersion. The method of separating the microballoons from the microballoon dispersion is not specifically limited, and can be selected from ordinary separation methods with no specific limitation. For example, filtration or centrifugal separation is employed.

### Sixth Step

The sixth step is step of removing the oily phase from inside of the microballoons produced in the fifth step to give hollow microballoons. The method for removing the oily phase from the microballoons is not specifically limited, and can be selected from ordinary separation methods with no specific limitation. For example, a circulation air drier, a spray drier, a fluidized bed drier, or a vacuum drier can be used. The temperature at drying is preferably 40 to 250° C., more preferably 50 to 200° C.

In the case where the hollow microballoons for CMP polishing pad are formed of an amide resin, these may be formed by interfacial polymerization. In the case of interfacial polymerization, after an O/W emulsion or a water-in-oil (W/O) emulsion (hereinafter this may be referred to as W/O emulsion) has been prepared, this may be polymerized at the interface of the emulsion to produce microballoons. In the present invention, any of an O/W emulsion or a W/O emulsion is selectable, but an O/W emulsion is preferred since interfacial polymerization of such an O/W emulsion can efficiently produce hollow microballoons. Hereinunder a production method for hollow microballoons by interfacial polymerization of an O/W emulsion is exemplified.

The polymerization method of an O/W emulsion in the case where the hollow microballoons for CMP polishing pad are formed of an amide resin is briefly divided into the following, a first step: a step of preparing (c) an oily phase containing a polyfunctional carboxylic acid compound having at least two carboxy groups and an organic solvent (hereinafter also referred to as component (c)), a second step: a step of preparing (d) an aqueous phase containing an emulsifier (hereinafter also referred to as component (d)), a third step: a step of mixing and stirring the component (c) and the component (d) to prepare an O/W emulsion in which the aqueous phase is a continuous phase and the oily phase is a disperse phase, a fourth step: a step of adding a polyfunctional amine compound having at least two amino groups to the O/W emulsion to promote interfacial polymerization on the O/W emulsion interface to form a resin film to give microballoons, thereby producing a microballoon dispersion where the microballoons are dispersed, a fifth step: a step of separating the microballoons from the microballoon dispersion, and a sixth step: a step of removing the organic solvent solution from inside of the microballoons.

### First Step:

The first step is a step of preparing the (c) oily phase containing a polyfunctional carboxylic acid compound having at least two carboxy groups and an organic solvent, which is to be a disperse phase in the O/W emulsion.

The step is a step of dissolving a polyfunctional carboxylic acid compound having at least wo carboxy groups in an organic solvent to be mentioned below to prepare an oily phase, and the compound may be dissolved in a known method to prepare a uniform solution.

The amount to be used of the polyfunctional carboxylic acid compound having at least wo carboxy groups is preferably 0.1 to 50 parts by mass relative to 100 parts by mass of the organic solvent, more preferably 0.5 to 20 parts by mass, even more preferably 1 to 10 parts by mass. In the case where the molar number of all the amino group-containing compounds of the polyfunctional amine compounds having at least two amino groups is referred to as (n2), relative to the molar number (n1) of the carboxylic acid groups that the polyfunctional carboxylic acid compound having at least two carboxy groups has, n1 and n2 preferably fall within a range of 0.5≤(n1)/(n2)≤2.

A catalyst to be mentioned below may be added to the component (c) for the purpose of promoting the interfacial polymerization reaction.

### Second Step:

The second step is a step of preparing the (d) aqueous phase containing an emulsifier and water, which is to be a continuous phase in the O/W emulsion.

The step is a step of dissolving an emulsifier to be mentioned below in water to prepare an aqueous phase, and an emulsifier may be dissolved in a known method to give a uniform solution.

In the present invention, the amount to be used of the emulsifier is 0.01 to 20 parts by mass relative to 100 parts by mass of water, preferably 0.1 to 10 parts by mass. Within the range, aggregation of the liquid drops of the disperse phase in the O/W emulsion can be prevented, and microballoons having a uniform average particle size are easy to produce.

A catalyst to be mentioned below may be added to the component (d) for promoting the interfacial polymerization reaction.

### Third Step:

The third step is a step of mixing and stirring the component (c) prepared in the first step and the component (d) prepared in the second step to prepare an O/W emulsion in which the component (d) is a continuous phase and the component (c) is a disperse phase.

In the present invention, the method of mixing and stirring the component (c) and the component (d) to give an O/W emulsion may be a method of mixing and stirring them in consideration of the particle size of the microballoons to be produced and according to an appropriate known method.

In particular, a method of preparing an O/W emulsion is preferably employed, in which the component (c) and the component (d) are, after having been mixed, dispersed by stirring using a known dispersing machine of a high-speed shear mode, a friction mode, a high-pressure jet mode or an ultrasonic wave mode. Among these, a high-speed shear mode is preferred. In the case where a high-speed shear mode dispersing machine is used, the rotation number is preferably 500 to 20,000 rpm, more preferably 1,000 to 10,000 rpm. The dispersion time is preferably 0.1 to 60 minutes, more preferably 0.5 to 30 minutes. The dispersion temperature is preferably 10 to 40° C.

In the present invention, the ratio by weight of the component (c) to the component (d) is preferably such that the component (d) is 100 to 1000 parts by mass relative to 100 parts by mass of the component (c), more preferably 150 to 500 parts by mass. Within the range, a good emulsion can be produced.

### Fourth Step:

The fourth step is a step of adding a polyfunctional amine compound having at least two amino groups to the O/W emulsion for interfacial polymerization on the O/W emulsion interface to form a resin film to give microballoons, thereby producing a microballoon dispersion where the microballoons are dispersed. The amount to be used of the polyfunctional amine compound having at least two amino groups is as described above.

The polyfunctional amine compound having at least two amino groups can be added to the O/W emulsion directly as it is, or can be added thereto after previously dissolved in water.

In the case where the compound is previously dissolved in water, preferably, the amount of water to be used is in a range of 50 to 10,000 parts by mass relative to 100 parts by mass of the amount of the polyfunctional amine compound having at least two amino groups.

The polymerization temperature is not specifically limited so far as the O/W emulsion is not broken at the temperature, and preferably the reaction is carried out within a range of 5 to 70° C. The polymerization time is not also specifically limited, so far as microballoons can be formed within the time, and is generally selected from a range of 0.5 to 24 hours.

### Fifth Step, Sixth Step

The fifth step and the sixth step are the same as in the case where the hollow microballoons for CMP polishing pad are formed of a melamine resin or a urea resin.

The components used in the present invention are described below.

In the present invention, as the emulsifier for the component (A) or the component (d), usable is a dispersant, a surfactant or a combination of these.

Examples of the dispersant include polyvinyl alcohol and modified derivatives thereof (for example, anion-modified polyvinyl alcohol), cellulosic compounds (for example, methyl cellulose, ethyl cellulose, hydroxyethyl cellulose, ethylhydroxyethyl cellulose, carboxymethyl cellulose, hydroxypropyl cellulose and saponified derivatives thereof), polyacrylic acid amide and derivatives thereof, ethylene-vinyl acetate copolymer, styrene-maleic anhydride copolymer, ethylene-maleic anhydride copolymer, isobutylene-maleic anhydride copolymer, polyvinyl pyrrolidone, ethylene-acrylic acid copolymer, vinyl acetate-acrylic acid copolymer, sodium polyacrylate, potassium polyacrylate, ammonium polyacrylate, partially neutralized derivatives of polyacrylic acid, sodium acrylate-acrylate copolymer, carboxymethyl cellulose, casein, gelatin, dextrin, chitin, chitosan, starch derivatives, gum arabic and sodium alginate.

Preferably, these dispersants do not react with or extremely hardly react with the polymerizable monomer used in the present invention. Therefore, it is desirable that those having a reactive amino group in the molecular chain, such as gelatin, are previously processed for treatment to lose reactivity.

The surfactant includes an anionic surfactant, a cationic surfactant, an ampholytic surfactant, and a nonionic surfactant. Two or more kinds of surfactants can be sued as combined.

The anionic surfactant includes a carboxylic acid or a salt thereof, a sulfate ester salt, a salt of a carboxymethylated substance, a sulfonic acid salt and a phosphate ester salt.

The carboxylic acid or a salt thereof includes a saturated or unsaturated fatty acid having 8 to 22 carbon atoms, or a salt thereof, and specific examples include capric acid, lauric acid, myristic acid, palmitic acid, stearic acid, arachidic acid, behenic acid, oleic acid, linolic acid, ricinoleic acid, and a mixture of higher fatty acids obtained by saponifying palm oil, palm kernel oil, rice bran oil or beef tallow. The salt includes salts of the above with sodium, potassium, ammonium or alkanolamine.

The sulfate ester salt includes a higher alcohol sulfate ester salt (a sulfate ester salt of an aliphatic alcohol having 8 to 18 carbon atoms), a higher alkyl ether sulfate ester salt (a sulfate ester salt of an ethylene oxide adduct of an aliphatic alcohol having 8 to 18 carbon atoms), a sulfated oil (an unsaturated oil or fat or an unsaturated wax is directly sulfated and neutralized), a sulfated fatty acid ester (a lower alcohol ester of an unsaturated fatty acid is sulfated and neutralized), and a sulfated olefin (an olefin having 12 to 18 carbon atoms is sulfated and neutralized). The salt includes a sodium salt, a potassium salt, an ammonium salt and an alkanolamine salt.

Specific examples of the higher alcohol sulfate ester salt include an octyl alcohol sulfate ester salt, a decyl alcohol sulfate ester salt, a lauryl alcohol sulfate ester salt, a stearyl alcohol sulfate ester salt, and a sulfate ester salt of an alcohol synthesized in an oxo method (Oxocol 900, tridecanol: by Kyowa Hakko Co., Ltd.).

Specific examples of the higher alkyl ether sulfate ester salt include a lauryl alcohol ethylene oxide (2 mols) adduct sulfate ester salt, and an octyl alcohol ethylene oxide (3 mols) adduct sulfate ester salt.

Specific examples of the sulfated oil include sodium, potassium, ammonium or alkanolamine salts of sulfated castor oil, peanut oil, olive oil, rapeseed oil, beef tallow or mutton tallow.

Specific examples of the sulfated fatty acid ester include sodium, potassium, ammonium or alkanolamine salts of sulfated butyl oleate or butyl ricinoleate.

The salt of a carboxymethylated compound includes a salt of a carboxymethylated aliphatic alcohol having 8 to 16 carbon atoms, and a salt of a carboxymethylated ethylene oxide adduct of an aliphatic alcohol having 8 to 16 carbon atoms.

Specific examples of the salt of a carboxymethylated aliphatic alcohol include an octyl alcohol carboxymethylated sodium salt, a decyl alcohol carboxymethylated sodium salt, a lauryl alcohol carboxymethylated sodium salt, and a tridecanol carboxymethylated sodium salt.

Specific example of the aliphatic alcohol ethylene oxide adduct carboxymethylated salt include an octyl alcohol ethylene oxide (3 mols) adduct carboxymethylated sodium salt, a lauryl alcohol ethylene oxide (4 mols) adduct carboxymethylated sodium salt, and a tridecanol ethylene oxide (5 mols) adduct carboxymethylated sodium salt.

The sulfonate salt includes an alkylbenzene sulfonate salt, an alkylnaphthalene sulfonate salt, a sulfosuccinic acid diester-type salt, an α-olefin sulfonate salt, an Igepon T-type salt, and other aromatic ring-containing compound sulfonate salts.

Specific examples of the alkylbenzene sulfonate salt include sodium dodecylbenzene sulfonate.

Specific examples of the alkylnaphthalene sulfonate salt include dodecylnapthalene sulfonate sodium salt.

Specific examples of the sulfosuccinic acid diester-type salt include sulfosuccinic acid di-2-ethylhexyl ester sodium salt.

The sulfonic acid salt of an aromatic ring-containing compound include an alkylated diphenyl ether mono- or di-sulfonate salt, and a styrenated phenolsulfonate salt.

The phosphate ester salt includes a higher alcohol phosphate ester salt, and a higher alcohol ethylene oxide adduct phosphate ester salt.

Specific examples of the higher alcohol phosphate ester salt include lauryl alcohol phosphoric acid monoester disodium salt, and lauryl alcohol phosphoric acid diester sodium salt.

Specific examples of the higher alcohol ethylene oxide adduct phosphate ester salt include oleyl alcohol ethylene oxide (5 mols) adduct phosphoric acid monoester disodium salt.

The cationic surfactant includes a quaternary ammonium salt-type surfactant and an amine salt-type surfactant.

The quaternary ammonium salt-type surfactant includes reaction products of a tertiary amine and a quaternizing agent (e.g., alkylating agent such as methyl chloride, methyl bromide, ethyl chloride, benzyl chloride, dimethyl sulfate, and ethylene oxide), such as lauryltrimethylammonium chloride, didecyldimethylammonium chloride, dioctyldimethylammonium bromide, stearyltrimethylammonium bromide, lauryldimethylbenzylammonium chloride (benzalkonium chloride), cetylpyridinium chloride, polyoxyethylene trimethylammonium chloride, and stearamidoethyldiethylmethylammonium methosulfate.

The amine-type surfactant is obtained by neutralizing a mono- to triamine with an inorganic acid (e.g., hydrochloric acid, nitric acid, sulfuric acid, hydroiodic acid) or an organic acid (e.g., acetic acid, formic acid, oxalic acid, lactic acid, gluconic acid, adipic acid, or alkylphosphoric acid). Examples of the primary amine salt-type surfactant include an inorganic acid salt or an organic acid salt of an aliphatic higher amine (higher amine such as laurylamine, stearylamine, cetylamine, hardened beef tallow amine, or rosin amine), and a higher fatty acid (e.g., stearic acid or oleic acid) salt of a lower amine.

Examples of the secondary amine-type surfactant include an inorganic acid salt or an organic acid salt of an aliphatic amine ethylene oxide adduct.

Examples of the tertiary amine-type surfactant include an inorganic acid salt or an organic acid salt of an aliphatic amine (e.g., triethylamine, ethyldimethylamine, N,N,N′,N′-tetramethylethylenediamine), an aliphatic amine ethylene oxide adduct, an alicyclic amine (e.g., N-methylpyrrolidine, N-methylpiperidine, N-methylhexamethyleneimine, N-methylmorpholine, 1,8-diazabicyclo(5,4,0)-7-undecene), or a nitrogen-containing heterocyclic aromatic amine (e.g., 4-dimethylaminopyridine, N-methylimidazole, 4,4′-dipyridyl), and an inorganic acid salt or an organic acid salt of a tertiary amine such as triethanolamine monostearate, and stearamidoethyldiethylmethylethanolamine.

The ampholytic surfactant includes a carboxylate salt-type ampholytic surfactant, a sulfate ester salt-type ampholytic surfactant, a sulfonate salt-type ampholytic surfactant, and a phosphate ester salt-type ampholytic surfactant. The carboxylate salt-type ampholytic surfactant includes an amino acid-type ampholytic surfactant and a betaine-type ampholytic surfactant.

The carboxylate salt-type ampholytic surfactant includes an amino acid-type ampholytic surfactant, a betaine-type ampholytic surfactant, and an imidazoline-type ampholytic surfactant. Among these, the amino acid-type ampholytic surfactant is an ampholytic surfactant having an amino group and a carboxy group in the molecule, and specifically, examples thereof include an alkylaminopropionate-type ampholytic surfactant (e.g., sodium stearylaminopropionate, sodium laurylaminopropionate), and an alkylaminoacetate-type ampholytic surfactant (e.g., sodium laurylaminoacetate).

The betaine-type ampholytic surfactant is an ampholytic surfactant having a quaternary ammonium salt-type cationic moiety and a carboxylate-type anionic moiety in the molecule, and examples thereof include an alkyldimethylbetaine (e.g., stearyl dimethylaminoacetate betaine, lauryl dimethylaminoacetate betaine), an amidobetaine (e.g., coconut oil fatty acid amide propylbetaine), and an alkyldihydroxyalkyl betaine (e.g., lauryldihydroxyethyl betaine).

Examples of the imidazoline-type ampholytic surfactant include 2-undecyl-N-carboxymethyl-N-hydroxyethylimidazolinium betaine.

Examples of other ampholytic surfactants include glycine-type ampholytic surfactants such as sodium lauroylglycine, sodium lauryldiaminoethylglycine, lauryldiaminoethylglycine hydrochloride, and dioctyldiaminoethylglycine hydrochloride, and sulfobetaine-type ampholytic surfactants such as pentadecylsulfotaurine.

The nonionic surfactant includes an alkylene oxide adduct-type nonionic surfactant and a polyalcohol-type nonionic surfactant.

The alkylene oxide adduct-type nonionic surfactant is obtained by reacting a polyalkylene glycol, which is obtained by directly adding an alkylene oxide to a higher alcohol, a higher fatty acid or an alkylamine, or by adding an alkylene oxide to a glycol, with a higher fatty acid, or is obtained by adding an alkylene oxide to an esterified product, which is obtained by reacting a higher fatty acid with a polyalcohol, or by adding an alkylene oxide to a higher fatty acid amide.

Examples of the alkylene oxide include ethylene oxide, propylene oxide and butylene oxide.

Specific examples of the alkylene oxide adduct-type nonionic surfactant include an oxyalkylene alkyl ether (e.g., octyl alcohol ethylene oxide adduct, lauryl alcohol ethylene oxide adduct, stearyl alcohol ethylene oxide adduct, oleyl alcohol ethylene oxide adduct, lauryl alcohol ethylene oxide propylene oxide block adduct), a polyoxyalkylene higher fatty acid ester (e.g., stearyl acid ethylene oxide adduct, lauryl acid ethylene oxide adduct), a polyoxyalkylene polyalcohol higher fatty acid ester (e.g., polyethylene glycol lauryl acid diester, polyethylene glycol oleic acid diester, polyethylene glycol stearic acid diester), a polyoxyalkylene alkyl phenyl ether (e.g., nonylphenol ethylene oxide adduct, nonylphenol ethylene oxide propylene oxide block adduct, octylphenol ethylene oxide adduct, bisphenol A ethylene oxide adduct, dinonylphenol ethylene oxide adduct, styrenated phenol ethylene oxide adduct), a polyoxyalkylene alkylamino ether (e.g., laurylamine ethylene oxide adduct, stearylamine ethylene oxide adduct), and a polyoxyalkylene alkylalkanolamide (e.g., hydroxyethylaluric acid amide ethylene oxide adduct, hydropropyloleic acid amide ethylene oxide adduct, dihydroxyethylaluric acid amide ethylene oxide adduct).

The polyalcohol-type nonionic surfactant includes a polyalcohol fatty acid ester, a polyalcohol fatty acid ester alkylene oxide adduct, a polyalcohol alkyl ether, and a polyalcohol alkyl ether alkylene oxide adduct.

Specific examples of the polyalcohol fatty acid ester include pentaerythritol monolaurate, pentaerythritol monooleate, sorbitan monolaurate, sorbitan monostearate, sorbitan monolaurate, sorbitan dilaurate, sorbitan dioleate, and sucrose monostearate.

Specific examples of the polyalcohol fatty acid ester alkylene oxide adduct include ethylene glycol monooleate ethylene oxide adduct, ethylene glycol monostearate ethylene oxide adduct, trimethylolpropane monostearate ethylene oxide propylene oxide random adduct, sorbitan monolaurate ethylene oxide adduct, sorbitan monostearate ethylene oxide adduct, sorbitan distearate ethylene oxide adduct, and sorbitan dilaurate ethylene oxide propylene oxide random adduct.

Specific examples of the polyalcohol alkyl ether include pentaerythritol monobutyl ether, pentaerythritol monolauryl ether, sorbitan monomethyl ether, sorbitan monostearyl ether, methyl glycoside, and lauryl glycoside.

Specific examples of the polyalcohol alkyl ether alkylene oxide adduct include sorbitan monostearyl ether ethylene oxide adduct, methyl glycoside ethylene oxide propylene oxide random adduct, lauryl glycoside ethylene oxide adduct, and stearyl glycoside ethylene oxide propylene oxide random adduct.

Among these, the emulsifier for use in the present invention is preferably selected from a dispersant and a nonionic surfactant, and specific examples of more preferred emulsifiers are mentioned below. In the case where the hollow microballoons for CMP polishing pad of the present invention are formed of melamine resin or a urea resin, the emulsifier is preferably a styrene-maleic anhydride copolymer, an ethylene-maleic anhydride copolymer or an isobutylene-maleic anhydride copolymer. By neutralizing these with an alkaline compound such as sodium hydroxide, a high-density anionic polymer is produced, and this can promote polymerization of a melamine formaldehyde prepolymer compound or a urea formaldehyde prepolymer compound.

In the case where the hollow microballoons for CMP polishing pad are formed of an amide resin, preferred is a sodium acrylate-acrylate copolymer. By selecting these, a stable emulsion can be formed.

In the present invention, the organic solvent used for the component (a) or the component (c) is not specifically limited so far as it can dissolve a polyfunctional carboxylic acid compound having at least two carboxy groups, and examples thereof include hydrocarbons, halides and ketones

Above all, preferred are those having a boiling point of 200° C. or lower, for removing the organic solvent from the inside of microballoons to give hollow microballoons, and more preferred are those having a boiling point of 150° C. or lower. Examples thereof are listed below.

### (Hydrocarbons)

Mentioned are aliphatic hydrocarbon having 6 to 11 carbon atoms, such as n-hexane, n-heptane and n-octane, an aromatic hydrocarbon such as benzene, toluene and xylene, and an alicyclic hydrocarbon such as cyclohexane, cyclopentane and methylcyclohexane.

### (Halides)

Mentioned are chloroform, dichloromethane, tetrachloroethane, and mono or dichlorobenzene.

### (Ketones)

Mentioned is methyl isobutyl ketone.

One alone or two or more kinds of these organic solvents can be used either singly or as a mixed solvent thereof.

In particular, the organic solvent for use in the present invention is more preferably n-hexane, n-heptane, n-octane, benzene, toluene or xylene.

In the present invention, for the purpose of more stabilizing the emulsion, an additive may be added to the aqueous phase within a range not detracting from the advantageous effects of the present invention. Such an additive includes a water-soluble salt such as sodium carbonate, calcium carbonate, potassium carbonate, sodium phosphate, potassium phosphate, calcium phosphate, sodium chloride or potassium chloride. One alone or two or more kinds of these additives can be used either singly or as combined.

Catalysts usable in the present invention are mentioned below.

In the case where the hollow microballoons for CMP polishing pad are formed of an amide resin, any suitable amidation catalyst is employable with no limitation. Specific examples include boron and sodium dihydrogen phosphate.

The hollow microballoons for CMP polishing pad of the present invention are suitable as hollow balloons for CMP polishing pad. By introducing the hollow microballoons into the polyurethane(urea) resin constituting CMP polishing pad, CMP polishing pad can be produced with excellent production stability, and the CMP polishing pad can express excellent polishing characteristics.

For producing such CMP polishing pad, any known method is employable with no specification, and by cutting and surface-polishing the polyurethane(urea) resin that contains the hollow microballoons for CMP polishing pad of the present invention, CMP polishing pad having fine pores on the polished surface of the polyurethane(urea) resin can be produced.

The polyurethane(urea) resin for use in the CMP polishing pad of the present invention may be produced in a known method with no specific limitation. For example, herein employable is a method of polymerizing a polymerizable composition that contains (B) a polyfunctional isocyanate compound (hereinafter also referred to as component (B)) and (C) a compound having at least two active hydrogen groups, such as a hydroxy group, a thiol group and an amino group (hereinafter also referred to as component (C)).

In the present invention, the polyurethane(urea) resin is a generic name for a polyurethane resin, a polyurea resin and a polyurethane-urea resin.

Constituent components of the polyurethane(urea) resin are individually described in detail hereinunder.

### <(B) Polyfunctional Isocyanate Compound: Component (B)>

The polyfunctional isocyanate compound (B) is a compound having at least two iso(thio)cyanate groups.

In the present specification, the iso(thio)cyanate group indicates an isocyanate group (NCO group), or an isothiocyanate group (NCS group). As the polyfunctional isocyanate compound (B), surely selectable is a compound having both groups of an isocyanate group and an isothiocyanate group. Accordingly, the number of the iso(thio)cyanate groups in the polyfunctional isocyanate compound (B) is a total number of the isocyanate group and the isothiocyanate group therein.

Above all, preferred is a compound having 2 to 6 iso(thio)cyanate groups in the molecule, more preferred is a compound having 2 to 4 such groups, and even more preferred is a compound having 2 to 3 such groups.

The component (B) can also be (B1) a urethane prepolymer (hereinafter also referred to as “component (B1)”), which is produced by reaction of (B11) a difunctional iso(thio)cyanate compound having two iso(thio)cyanate groups in the molecule (hereinafter also referred to as “component (B11)”) to be mentioned below, and (C11) a difunctional active hydrogen-containing compound having two active hydrogen groups in the molecule (hereinafter also referred to as “component (C11)”) also to be mentioned below. As the urethane prepolymer (B1) corresponding to the component (B), any one having at least two unreacted isocyanate groups or isothiocyanate groups and generally used in the art can be used in the present invention with no limitation, and preferred is a urethane prepolymer (B1) having at least two isocyanate groups.

The active hydrogen group in the component (C11) is a group selected from a hydroxy group, a thiol group and an amino group.

The component (B) can be broadly grouped into an aliphatic isocyanate, an alicyclic isocyanate, an aromatic isocyanate, an isothiocyanate, other isocyanates, and the urethane prepolymer (B1). For the component (B), one kind of compound can be used, or plural kinds of compounds can be used. In the case where plural kinds of compounds are used, the basis mass is a total amount of the plural kinds of compounds. Specific examples of the component (B) are listed below.

### Aliphatic Isocyanate: Component (B)

A difunctional isocyanate (corresponding to the component (B11) that constitutes the urethane prepolymer (B1) to be mentioned below), such as ethylene diisocyanate, trimethylene diisocyanate, tetramethylene diisocyanate, hexamethylene diisocyanate, octamethylene diisocyanate, nonamethylene diisocyanate, 2,2′-dimethylpentane diisocyanate, 2,2,4-trimethylhexamethylene diisocyanate, decamethylene diisocyanate, butene diisocyanate, 1,3-butadiene 1,4-diisocyanate, 2,4,4-trimethylhexamethylene diisocyanate, 1,6,11-trimethylundecamethylene diisocyanate, 1,3,6-trimethylhexamethylene diisocyanate, 1,8-diisocyanate 4-isocyanate methyloctane, 2,5,7-trimethyl-1,8-diisocyanate 5-isocyanate methyloctane, bis(isocyanatoethyl) carbonate, bis(isocyanatoethyl) ether, 1,4-butylene glycol dipropyl ether-ω,ω′-diisocyanate, lysine diisocyanate methyl ester, and 2,4,4-trimethylhexamethylene diisocyanate.

### Alicyclic Isocyanate: Component (B)

A difunctional isocyanate (corresponding to the component (B11) that constitute the urethane prepolymer (B1) to be mentioned in detail hereinunder), such as isophorone diisocyanate, (bicyclo[2.2.1]heptane-2,5-diyl)bismethylene diisocyanate, (bicyclo[2.2.1]heptane-2,6-diyl)bismethylene diisocyanate, 2β,5α-bis(isocyanate)norbornane, 2β,5β-bis(isocyanate)norbornane, 2β,6α-bis(isocyanate)norbornane, 2β,6β-bis(isocyanate)norbornane, 2,6-(diisocyanatomethyl)furan, bis(isocyanatomethyl)cyclohexane, dicyclohexylmethane-4,4′-diisocyanate, 4,4-isopropylidene-bis(cyclohexyl isocyanate), cyclohexane diisocyanate, methylcyclohexane diisocyanate, dicyclohexyldimethylmethane diisocyanate, 2,2′-dimethyldicyclohexylmethane diisocyanate, bis(4-isocyanate-n-butylidene)pentaerythritol, dimer acid diisocyanate, 2,5-bis(isocyanatomethyl)-bicyclo[2,2,1]-heptane, 2,6-bis(isocyanatomethyl)-bicyclo[2,2,1]-heptane, 3,8-bis(isocyanatomethyl)tricyclodecane, 3,9-bis(isocyanatomethyl)tricyclodecane, 4,8-bis(isocyanatomethyl)tricyclodecane, 4,9-bis(isocyanatomethyl)tricyclodecane, 1,5-diisocyanatedecalin, 2,7-diisocyanatedecalin, 1,4-diisocyanatedecalin, 2,6-diisocyanatedecalin, bicyclo[4.3.0]nonane-3,7-diisocyanate, bicyclo[4.3.0]nonane-4,8-diisocyanate, bicyclo[2.2.1]heptane-2,5-diisocyanate, bicyclo[2.2.1]heptane-2,6-diisocyanate, bicyclo[2,2,2]octane-2,5-diisocyanate, bicyclo[2,2,2]octane-2,6-diisocyanate, tricyclo[5.2.1.0^{2,6}]decane-3,8-diisocyanate, and tricyclo[5.2.1.0^{2,6}]decane-4,9-diisocyanate.

A polyfunctional isocyanate monomer such as 2-isocyanatomethyl-3-(3-isocyanatopropyl)-5-isocyanatomethyl-bicyclo[2,2,1]-heptane, 2-isocyanatomethyl-3-(3-isocyanatopropyl)-6-isocyanatomethyl-bicyclo[2,2,1]-heptane, 2-isocyanatomethyl-2-(3-isocyanatopropyl)-5-isocyanatomethyl-bicyclo[2,2,1]-heptane, 2-isocyanatomethyl-2-(3-isocyanatopropyl)-6-isocyanatomethyl-bicyclo[2,2,1]-heptane, 2-isocyanatomethyl-3-(3-isocyanatopropyl)-5-(2-isocyanatoethyl)-bicyclo[2,2,1]-heptane, 2-isocyanatomethyl-3-(3-isocyanatopropyl)-6-(2-isocyanatoethyl)bicyclo[2,2,1]-heptane, 2-isocyanatomethyl-2-(3-isocyanatopropyl)-5-(2-isocyanatoethyl)-bicyclo[2,2,1]heptane, 2 isocyanatomethyl-2-(3-isocyanatopropyl)-6-(2-isocyanatoethyl)-bicyclo[2,2,1]-heptane, and 1,3,5-tris(isocyanatomethyl)cyclohexane.

### Aromatic Isocyanate: Component (B)

A difunctional isocyanate (corresponding to the component (B11) that constitute the urethane prepolymer (B1) to be mentioned in detail hereinunder), such as xylylene diisocyanate (o-, m-, p-), tetrachloro-m-xylylene diisocyanate, methylenediphenyl-4,4′-diisocyanate, 4-chloro-m-xylylene diisocyanate, 4,5-dichloro-m-xylylene diisocyanate, 2,3,5,6-tetrabromo-p-xylylene diisocyanate, 4-methyl-m-xylylene diisocyanate, 4-ethyl-m-xylylene diisocyanate, bis(isocyanatoethyl)benzene, bis(isocyanatopropyl)benzene, 1,3-bis(α,α-dimethylisocyanatomethyl)benzene, 1,4-bis(α,α-dimethylisocyanatomethyl)benzene, α,α,α′,α′-tetramethylxylylene diisocyanate, bis(isocyanatobutyl)benzene, bis(isocyanatomethyl)naphthalene, bis(isocyanatomethyl)diphenyl ether, bis(isocyanatoethyl) phthalate, 2,6-diisocyanatomethyl)furan, phenylene diisocyanate (o-, m-, p-), tolylene diisocyanate, ethylphenylene diisocyanate, isopropylphenylene diisocyanate, dimethylphenylene diisocyanate, diethylphenylene diisocyanate, diisopropylphenylene diisocyanate, trimethylbenzene triisocyanate, benzene triisocyanate, 1,3,5-triisocyanatomethylbenzene, 1,5-naphthalene diisocyanate, methylnaphthalene diisocyanate, biphenyl diisocyanate, 2,4-tolylene diisocyanate, 2,6-tolylene diisocyanate, 4,4′-diphenylmethane diisocyanate, 2,2′-diphenylmethane diisocyanate, 2,4′-diphenylmethane diisocyanate, 3,3′-dimethyldiphenylmethane-4,4′-diisocyanate, bibenzyl-4,4′-diisocyanate, bis(isocyanatophenyl)ethylene, 3,3′-dimethoxybiphenyl-4,4′-diisocyanate, phenylisocyanatomethyl isocyanate, phenylisocyanatoethyl isocyanate, tetrahydronaphthalene diisocyanate, hexahydrobenzene diisocyanate, hexahydrodiphenylmethane-4,4′-diisocyanate, diphenyl ether diisocyanate, ethylene glycol diphenyl ether diisocyanate, 1,3-propylene glycol diphenyl ether diisocyanate, benzophenone diisocyanate, diethylene glycol diphenyl ether diisocyanate, dibenzofuran diisocyanate, carbazole diisocyanate, ethylcarbazole diisocyanate, dichlorocarbazole diisocyanate, 2,4-tolylene diisocyanate, and 2,6-tolylene diisocyanate.

A polyfunctional isocyanate compound, such as mesitylene triisocyanate, triphenylmethane triisocyanate, polymeric MDI, naphthalene triisocyanate, diphenylmthane-2,4,4′-triisocyanate, 3-methyl-diphenylmethane-4,4′,6-triisocyanate, and 4-methyl-diphenylmethane-2,3,4′,5,6-pentaisocyanate.

### Isothiocyanate: Component (B)

A difunctional isothiocyanate (corresponding to the component (B11) that constitutes the urethane prepolymer (B1) to be mentioned in detail hereinunder), such as p-phenylene diisothiocyanate, xylylene 1,4-diisothiocyanate, and ethylidyne diisothiocyanate.

### Other Isocyanate: Component (B)

The other isocyanate includes a polyfunctional isocyanate having a biuret structure, a uretdione structure or an isocyanurate structure, for which diisocyanates such as hexamethylene diisocyanate or tolylene diisocyanate are main materials (for example, JP2004-534870A discloses a method for modifying a biuret structure, a uretdione structure or an isocyanurate structure of an aliphatic polyisocyanate), and a polyfunctional isocyanate as an adduct with a tri- or higher polyol such as trimethylolpropane (as disclosed in a document (Polyurethane Resin Handbook, edited by Keiji Iwata, published by Nikkan Kogyo Shimbun Co. (1987)).

### (B1) Urethane Prepolymer: Component (B) Having an Iso(Thio)Cyanate Group at Both Terminals

In the present invention, the urethane prepolymer (B1) produced by reaction of the above-mentioned component (B11) and the component (C11) to be mentioned below can be used as the component (B).

Not specifically limited, the urethane prepolymer (B1) preferably uses the monomers exemplified below as the component (B11). Specifically, preferred is use of 1,5-naphthalene diisocyanate, xylene diisocyanate (o-, m-, p-), 2,4-tolylene diisocyanate, 2,6-tolylene diisocyanate, phenylene diisocyanate (o-, m-, p-), 2,2′-diphenylmethane diisocyanate, 2,4′-diphenylmethane diisocyanate 4,4′-diphenylmethane diisocyanate, isophorone diisocyanate, 1,3-bis(isocyanatomethyl)cyclohexane, dicyclohexylmethane-4,4′-diisocyanate, and (bicyclo[2.2.1]heptane-2,5(2,6)-diylkismethylene diisocyanate. Preferably, these are reacted with the component (C11) to produce the component (B1) having an isocyanate group and/or an isothiocyanate group at both terminals.

In order that the polyurethane(urea) resin obtained finally can exhibit especially excellent characteristics, preferably, the urethane prepolymer (B1) is produced by using at least one component (C11) having a molecular weight (number-average molecular weight) of 300 to 2000. The active hydrogen group indicates a hydroxy group, a thiol group, or an amino group. In particular, in consideration of reactivity, the active hydrogen group in the component (C11) is preferably a hydroxy group.

Regarding the use of component (C11) having a molecular weight (number average molecular weight) of 300 to 2000, different kinds of the components or the components having a different molecular weight can be used as combined. For controlling the hardness and the strength of the polyurethane(urea) resin to be obtained finally, the urethane prepolymer (B1) is preferably one produced by combination of the component (C11) having a molecular weight (number-average molecular weight) of 300 to 2000 and the component (C11) having a molecular weight (number-average molecular weight) of 90 to 300. In that case, though depending on the kind of the component (C11) and the component (B11) and the amount to be used of these, it is preferable that the amount of the component (C11) having a molecular weight of 90 to 300 is 0 to 50 parts by mass relative to 100 parts by mass of the component (C11) having a molecular weight of 300 to 2000, more preferably the amount of the component (C11) having a molecular weight of 90 to 300 is 1 to 40 parts by mass.

The urethane prepolymer (B1) must have an iso(thio)cyanate group at both terminals of the molecule. For this, preferably, the urethane prepolymer (B1) is produced under the condition that the total molar number (n5) of the iso(thio)cyanate groups in the component (B11) and the total molar number (n6) of the active hydrogen groups (hydroxy group, thiol group or amino group) in the component (C11) fall within a range of 1<(n5)/(n6)≤2.3. In the case where, for two or more kinds of the terminals of the molecule, the component (B11) is used, the molar number (n5) of the iso(thio)cyanate groups is surely the total molar number of the iso(thio)cyanate groups of the component (B11). Also, the molar number (n6) of the active hydrogen groups of two or more kinds of the component (C11) is surely the total molar number of the active hydrogens of the active hydrogen groups. Also in the case where the active hydrogen group is a primary amino group, the primary amino group is considered as 1 mol. Namely, in the primary amino group, considerable energy is required in reacting the second amino group (—NH) (even in the primary amino group, the second —NH is difficult to react). Therefore, in the present invention, in the case of using the component (C11) having a primary amino group, the primary amino group can be calculated as one mol.

Regarding the iso(thio)cyanate equivalent (total of the isocyanate equivalent and/or the isothiocyanate equivalent) of the urethane prepolymer (B1), the iso(thio)cyanate group that the urethane prepolymer (B1) has can be quantitatively determined according to JIS K 7301. The iso(thio)cyanate group can be quantitatively determined by a back titration method mentioned below. First, the urethane prepolymer (B1) produced is dissolved in a dry solvent. Next, di-n-butylamine having a known concentration is added to the dry solvent in an amount obviously excessive over the amount of the iso(thio)cyanate groups that the urethane prepolymer (B1) has to thereby react all the iso(thio)cyanate groups of the urethane prepolymer (B1) and di-n-butylamine. Next, di-n-butylamine not consumed (not involved in the reaction) is titered with an acid to determine the amount of the consumed di-n-butylamine. The amount of the consumed di-n-butylamine is the same as the amount of the iso(thio)cyanate groups that the urethane prepolymer (B1) has, and therefore, the iso(thio)cyanate equivalent can be calculated. The urethane prepolymer (B1) is a linear urethane prepolymer having an iso(thio)cyanate group at both terminals, and therefore the number-average molecular weight of the urethane prepolymer (B1) is two times the iso(thio)cyanate equivalent. The molecular weight of the urethane prepolymer (B1) easily matches the value measured by gel permeation chromatography (GPC). In the case where the urethane prepolymer (B1) and the component (B11) are used together, a mixture of the two may be measured according to the above-mentioned method.

Not specifically limited, the iso(thio)cyanate equivalent of the urethane prepolymer (B1) is preferably 300 to 5000, more preferably 350 to 3000, even more preferably 350 to 2000. Though not clear, the reason is considered as follows. By using the urethane prepolymer (B1), it is considered that the crosslinking points can easily disperse in the polyurethane(urea) resin and can randomly and uniformly exist therein, and the resin can therefore exhibit stable performance. With that, the polyurethane(urea) resin using the urethane prepolymer (B1) can be readily controlled in producing it. For example, it is considered that the polymerizable composition for use in the present invention can be favorably used in producing polishing pads using it. It is considered that the effect can be expressed even when the average iso(thio)cyanate equivalent of the poly-iso(thio)cyanate compound is 300 to 5000 in the case of using the urethane prepolymer (B1) and the component (B11) as combined. However, it is considered that the effect can be remarkable in the case of the urethane prepolymer (B1) alone.

Regarding the production method for the urethane prepolymer (B1) for use in the present invention, the component (C11) having at least two active hydrogen groups such as a hydroxy group, an amino group or a thiol group in the molecule is reacted with the component (B11) to produce the urethane prepolymer (B1) having an isocyanate group or an isothiocyanate group at the terminal of the molecule. The production method is not limited at all so far as a prepolymer having an isocyanate group or an isothiocyanate group at the terminal can be produced.

As mentioned above, a preferred blending ratio of the component (C11) and the component (B11) for producing the urethane prepolymer (B1) is mentioned below. Specifically, it is preferable that the prepolymer is produced so that the molar number (n5) of the iso(thio)cyanate groups in the component (B11) and the molar number (n6) of the active hydrogens in the component (C11) can fall within a range of 1<(n5)/(n6)≤2.3.

In the reaction for producing the urethane prepolymer (B1), heating or addition of a urethanation catalyst can be carried out, as needed.

Most preferred examples of the component (B) for use in the present invention are, from the viewpoint of the strength of the polyurethane(urea) resin to be formed and the viewpoint of reactivity control, an alicyclic isocyanate such as isophorone diisocyanate, 1,3-bis(isocyanatomethyl)cyclohexane, and (bicyclo[2.2.1]heptane-2,5(2,6)-diylkismethylene diisocyanate, an aromatic isocyanate such as 2,4-tolylene diisocyanate, 2,6-tolylene diisocyanate, 4,4′-diphenylmethane diisocyanate, and xylene diisocyanate (o-, m-. p-), a polyfunctional isocyanate having a biuret structure, a uretdione structure or an isocyanurate structure, for which diisocyanates such as hexamethylene diisocyanate or tolylene diisocyanate are main materials, a polyfunctional isocyanate as an adduct with a tri- or higher polyol, and the urethane prepolymer (B1).

Among these, especially preferred is the urethane prepolymer (B1).

### <(C) Compound Having at Least Two Active Hydrogen Groups: Component (C)>

For the compound (C) having at least two active hydrogen groups for use herein, any compound having at least two groups selected from the group consisting of a hydroxy group, a thiol group and an amino group in one molecule can be used with no limitation. Needless-to-say, a compound having any two or all of a hydroxy group, a thiol group and an amino group can be selected for use herein.

In particular, the component (C) preferably contains (CA) a compound having two or more amino groups (hereinafter also referred to as component (CA)), more preferably (CB) a compound having three or more of a hydroxy group and/or a thiol group (hereinafter also referred to as component (CB)). In the present specification, a compound having at least a number n of a hydroxy group and/or a thiol group means a compound in which the total number of the hydroxy group and the thiol group is at least n, and it may be a compound having a hydroxy group but not having a thiol group, or a compound having a thiol group but not having a hydroxy group, or a compound having both a hydroxy group and a thiol group.

The component (CB) is especially preferably a compound having at least five groups of a hydroxy group and/or a thiol group. The molar number of the hydroxy group and/or the thiol group by mass of the component (CB) is preferably 0.5 mmol/g to 35 mmol/g, more preferably 0.8 mmol/g to 20 mmol/g.

### ((CA) Compound Having Two or More Amino Groups: Component (CA))

For the compound (CA) having two or more amino groups in the component (C), any compound having two or more groups of a primary and/or secondary amino groups in one molecule can be used with no limitation. The compound having two or more amino groups is roughly grouped into an aliphatic amine, an alicyclic amine, an aromatic amine, and a polyrotaxane having an amino group polymerizable with an isocyanate group.

### Aliphatic Amine: Component (CA)

A difunctional amine (corresponding to the component (C11) constituting the urethane prepolymer (B1)), such as ethylenediamine, hexamethylenediamine, nonamethylenediamine, undecanemethylenediamine, dodecamethylenediamine, metaxylylenediamine, 1,3-propanediamine, and putrescine.

### Alicyclic Amine: Component (CA)

A difunctional amine (corresponding to the component (C11) constituting the urethane prepolymer (B1)), such as isophoronediamine and cyclohexyldiamine.

### Aromatic Amine: Component (CA)

A difunctional amine (corresponding to the component (C11) constituting the urethane prepolymer (B1)), such as 4,4′-methylenebis(o-chloroaniline) (MOCA), 2,6-dichloro-p-phenylenediamine, 4,4′-methylenebis(2,3-dichloroaniline), 4,4′-methylenebis(2-ethyl-6-methylaniline), 3,5-bis(methylthio)-2,4-toluenediamine, 3,5-bis(methylthio)-2,6-toluenediamine, 3,5-diethyltoluene-2,4-diamine, 3,5-diethyltoluene-2,6-diamine, trimethylene glycol-di-p-aminobenzoate, polytetramethylene glycol-di-p-aminobenzoate, 4,4′-diamino-3,3′,5,5′-tetraethyldiphenylmethane, 4,4′-diamino-3,3′-diisopropyl-5,5′-dimethyldiphenylmethane, 4,4′-diamino-3,3′-5,5′-tetraisopropyldiphenylmethane, 1,2-bis(2-aminophenylthio)ethane, 4,4′-diamino-3,3′-diethyl-5,5′-dimethyldiphenylmethane, N,N′-di-sec-butyl-4,4′-diaminodiphenylmethane, 3,3′-diethyl-4,4′-diaminodiphenylmethane, m-xylylenediamine, N,N′-di-sec-butyl-p-phenylenediamine, m-phenylenediamine, p-xylylenediamine, p-phenylenediamine, 3,3′-methylenebis(methyl-6-aminobenzoate), 2-methylpropyl 2.4-diamino-4-chlorobenzoate, isopropyl 2,4-diamino-4-chlorobenzoate, isopropyl 2,4-diamino-4-chlorophenylacetate, di-(2-aminophenyl)thioethyl terephthalate, diphenylmethanediamine, tolylenediamine, and piperazine.

A polyfunctional amine such as 1,3,5-benzenetriamine and melamine.

### Polyrotaxane Having an Amino Group: Component (CA)

The polyrotaxane having an amino group for use in the present invention is not specifically limited, and for example, polyrotaxanes described in WO2018/092826 are exemplified.

Among the components (CA) for use in the present invention, preferred are 4,4′-methylenebis(o-chloroaniline) (MOCA), 4,4′-diamino-3,3′-diethyl-5,5′-dimethyldiphenylmethane, 3,5-diethyltoluene-2,4-diamine, 3,5-diethyltoluene-2,6-diamine, 3,5-bis(methylthio)-2,4-toluenediamine, 3,5-bis(methylthio)-2,6-toluenediamine, and trimethylene glycol di-p-aminobenzoate.

Among the component (C), the compound having a hydroxy group and/or a thiol group is roughly grouped into an aliphatic alcohol, alicyclic alcohol, an aromatic alcohol, a polyester polyol, a polyether polyol, a polycaprolactone polyol, a polycarbonate polyol, a polyacryl polyol, a castor oil polyol, a thiol, an OH/SH polymerizable group-containing monomer, and a polyrotaxane having a hydroxy group and/or a thiol group. Specific examples thereof are shown below.

### ((C) Compound Having at Least Two Hydroxy Groups: Component (C))

### Aliphatic Alcohol: Component (C)

A difunctional polyol (corresponding to the component (C11) constituting the urethane prepolymer (B1)), such as ethylene glycol, diethylene glycol, propylene glycol, dipropylene glycol, butylene glycol, 1,5-dihydroxypentane, 1,6-dihydroxyhexane, 1,7-dihydroxyheptane, 1,8-dihydroxyoctane, 1,9-dihydroxynonane, 1,10-dihydroxydecane, 1,11-dihydroxyundecane, 1,12-dihydroxydodecane, neopentyl glycol, glyceryl monooleate, monoelaidin, polyethylene glycol, 3-methyl-1,5-dihydroxypentane, dihydroxyneopentyl, 2-ethyl-1,2-dihydroxyhexane, and 2-methyl-1,3-dihydroxypropane.

A polyfunctional polyol (corresponding to the component (CB)), such as glycerin, trimethylolethane, trimethylolpropane, ditrimethylolpropane, trimethylolpropane tripolyoxyethylene ether (e.g., TMP-30, TMP-60 and TMP-90 by Nippon Nyukazai Co., Ltd.), butanetriol, 1,2-methyl glucoside, pentaerythritol, dipentaerythritol, tripentaerithritol, sorbitol, erythritol, threitol, ribitol, arabinitol, xylitol, allitol, mannitol, dulcitol, iditol, glycol, inositol, hexanetriol, triglycerol, diglycerol, and triethylene glycol.

### Alicyclic Alcohol: Component (C)

A difunctional polyol (corresponding to the component (C11) constituting the urethane prepolymer (B)), such as hydrogenated bisphenol A, cyclobutanediol, cyclopentanediol, cyclohexanediol, cycloheptanediol, cyclooctanediol, cyclohexanedimethanol, hydroxypropylcyclohexanol, tricyclo[5,2,1,0^{2,6}]decane-dimethanol, bicyclo[4,3,0]-nonanediol, dicyclohexanediol, tricyclo[5,3,1,1^{3,9}]dodecanediol, bicyclo[4,3,0]nonanedimethanol, tricyclo[5,3,1,1^{3,9}]dodecane-diethanol, hydroxypropyltricyclo[5,3,1,1^{3,9}]dodecanol, spiro[3,4]octanediol, butylcyclohexanediol, 1,1′-bicyclohexylidenediol, 1,4-cyclohexanedimethanol, 1,3-cyclohexanedimethanol, 1,2-cyclohexanedimethanol, and o-dihydroxyxylylene.

A polyfunctional polyol (corresponding to the component (CB)), such as tris(2-hydroxyethyl) isocyanurate, cyclohexanetriol, sucrose, maltitol and lactitol.

### Aromatic Alcohol: Component (C)

A difunctional polyol (corresponding to the component (C11) constituting the urethane prepolymer (B1)), such as dihydroxynaphthalene, dihydroxybenzenes, bisphenol A, bisphenol F, xylylene glycol, tetrabromobisphenol A, bis(4-hydroxyphenyl) methane, 1,1-bis(4-hydroxyphenyl) ethane, 1,2-bis(4-hydroxyphenyl) ethane, bis(4-hydroxyphenyl)phenylmethane, bis(4-hydroxyphenyl)diphenylmethane, bis(4-hydroxyphenyl)-1-naphthylmethane, 1,1-bis(4-hydroxyphenyl)-1-phenylethane, 2-(4-hydroxyphenyl)-2-(3-hydroxyphenyl)propane, 2,2-bis(4-hydroxyphenyl)butane, 1,1-bis(4-hydroxyphenyl)butane, 2,2-bis(4-hydroxyphenyl)-3-methylbutane, 2,2-bis(4-hydroxyphenyl)pentane, 3,3-bis(4-hydroxyphenyl)pentane, 2,2-bis(4-hydroxyphenyl) hexane, 2,2-bis(4-hydroxyphenyl) octane, 2,2-bis(4-hydroxyphenyl)-4-methylpentane, 2,2-bis(4-hydroxyphenyl)heptane, 4,4-bis(4-hydroxyphenyl) heptane, 2,2-bis(4-hydroxyphenyl)tridecane, 2,2-bis(4-hydroxyphenyl) octane, 2,2-bis(3-methyl-4-hydroxyphenyl)propane, 2,2-bis(3-ethyl-4-hydroxyphenyl)propane, 2,2-bis(3-n-propyl-4-hydroxyphenyl)propane, 2,2-bis(3-isopropyl-4-hydroxyphenyl)propane, 2,2-bis(3-sec-butyl-4-hydroxyphenyl)propane, 2,2-bis(3-tert-butyl-4-hydroxyphenyl)propane, 2,2-bis(3-cyclohexyl-4-hydroxyphenyl)propane, 2,2-bis(3-allyl-4′-hydroxyphenyl)propane, 2,2-bis(3-methoxy-4-hydroxyphenyl)propane, 2,2-bis(3,5-dimethyl-4-hydroxyphenyl)propane, 2,2-bis(2,3,5,6-tetramethyl-4-hydroxyphenyl)propane, bis(4-hydroxyphenyl)cyanomethane, 1-cyano-3,3-bis(4-hydroxyphenyl)butane, 2,2-bis(4-hydroxyphenyl)hexafluoropropane, 1,1-bis(4-hydroxyphenyl)cyclopentane, 1,1-bis(4-hydroxyphenyl)cyclohexane, 1,1-bis(4-hydroxyphenyl)cycloheptane, 1,1-bis(3-methyl-4-hydroxyphenyl)cyclohexane, 1,1-bis(3,5-dimethyl-4-hydroxyphenyl)cyclohexane, 1,1-bis(3,5-dichloro-4-hydroxyphenyl)cyclohexane, 1,1-bis(3-methyl-4-hydroxyphenyl)-4-methylcyclohexane, 1,1-bis(4-hydroxyphenyl)-3,3,5-trimethylcyclohexane, 2,2-bis(4-hydroxyphenyl)norbornane, 2,2-bis(4-hydroxyphenyl) adamantane, 4,4′-dihydroxydiphenyl ether, 4,4′-dihydroxy-3,3′-dimethyldiphenyl ether, ethylene glycol bis(4-hydroxyphenyl) ether, 4,4′-dihydroxydiphenyl sulfide, 3,3′-dimethyl-4,4′-dihydroxydiphenyl sulfide, 3,3′-dicyclohexyl-4,4′-dihydroxydiphenyl sulfide, 3,3′-diphenyl-4,4′-dihydroxydiphenyl sulfide, 4,4′-dihydroxydiphenyl sulfoxide, 3,3′-dimethyl-4,4′-dihydroxydiphenyl sulfoxide, 4,4′-dihydroxydiphenyl sulfone, 4,4′-dihydroxy-3,3′-dimethyldiphenyl sulfone, bis(4-hydroxyphenyl) ketone, bis(4-hydroxy-3-methylphenyl) ketone, 7,7′-dihydroxy-3,3′,4,4′-tetrahydro-4,4,4′,4′-tetramethyl-2,2′-spirobi(2H-1-benzopyran), trans-2,3-bis(4-hydroxyphenyl)-2-butane, 9,9-bis(4-hydroxyphenyl)fluorene, 3,3-bis(4-hydroxyphenyl)-2-butanone, 1,6-bis(4-hydroxyphenyl)-1,6-hexanedione, 4,4′-dihydroxybiphenyl, m-dihydroxyxylylene, p-dihydroxyxylylene, 1,4-bis(2-hydroxyethyl)benzene, 1,4-bis(3-hydroxypropyl)benzene, 1,4-bis(4-hydroxybutyl)benzene, 1,4-bis(5-hydroxypentyl)benzene, 1,4-bis(6-hydroxyhexyl)benzene, 2,2-bis[4-(2″-hydroxyethyloxy)phenyl]propane, hydroquinone and resorcin.

A polyfunctional polyol (corresponding to the component (CB)), such as trihydroxynaphthalene, tetrahydroxynaphthalene, benzenetriol, biphenyltetraol, pyrogallol, (hydroxynaphthyl)pyrogallol, and trihydroxyphenanthrene.

### Polyester Polyol: Component (C)

This includes a compound obtained by condensation of a polyol and a polybasic acid. Above all, the number-average molecular weight thereof is preferably 400 to 2000, more preferably 500 to 1500, most preferably 600 to 1200. A compound having (two) hydroxy groups (in the molecule) at both terminals alone of the molecule corresponds to the component (C11) that constitutes the urethane prepolymer (B1), and a compound having three or more hydroxy groups in the molecule corresponds to the component (CB).

Here, the polyol includes ethylene glycol, 1,2-propanediol, 1,3-butanediol, 1,4-butanediol, 3-methyl-1,5-pentanediol, 1,6-hexanediol, 3,3′-dimethylolheptane, 1,4-cyclohexanedimethanol, neopentyl glycol, 3,3-bis(hydroxymethyl)heptane, diethylene glycol, dipropylene glycol, glycerin, and trimethylolpropane. One alone or two or more kinds of these can be used either singly or as combined. The polybasic acid includes succinic acid, adipic acid, azelaic acid, sebacic acid, dodecanedicarboxylic acid, cyclopentanedicarboxylic acid, cyclohexanedicarboxylic acid, orthophthalic acid, isophthalic acid, terephthalic acid, and naphthalenedicarboxylic acid. One alone or two or more kinds of these can be used either singly or as combined.

These polyester polyols are available as chemical reagents or industrially, and examples of commercial products thereof include “Polylite (registered trademark)” series by DIC Corporation, “Nipporane (registered trademark)” series by Nippon Polyurethane Industry Co., Ltd., “Maximol (registered trademark)” series by Kawasaki Kasei Chemicals Ltd., and “Kuraray Polyol (registered trademark)” series by Kuraray Corporation.

### Polyether Polyol: Component (C)

This includes a compound obtained by ring-cleavage polymerization of an alkylene oxide, or a compound obtained by reaction of a compound having at least two active hydrogen-containing groups in the molecule and an alkylene oxide and a modified derivative thereof. Above all, preferred are those having a number-average molecular weight of 400 to 2000, more preferably 500 to 1500, most preferably 600 to 1200. A compound having (two) hydroxy groups (in the molecule) at both terminals alone of the molecule corresponds to the component (C11) that constitutes the urethane prepolymer (B1), and a compound having three or more hydroxy groups in the molecule corresponds to the component (CB).

Here, the polyether polyol includes a polymer polyol, a urethane-modified polyether polyol, and a polyether ester copolymer polyol. The compound having at least two active hydrogen groups in the molecule includes a polyol compound such as glycol and glycerin having at least one hydroxy group in the molecule, such as water, ethylene glycol, propylene glycol, butanediol, glycerin, trimethylolpropane, hexanetriol, triethanolamine, diglycerin, pentaerythritol, trimethylolpropane and hexanetriol. One alone or two or more kinds of these can be used either singly or as combined.

The alkylene oxide includes a cyclic ether compound such as ethylene oxide, propylene oxide and tetrahydrofuran, and one alone or two or more kinds of these can be used either singly or as combined.

These polyether polyols are available as chemical reagents or industrially, and examples of commercial products thereof include “Exenol (registered trademark)” series by AGC Corporation, “Emalstar (registered trademark)”, and “Adeka Polyether” series by Adeka Corporation.

### Polycaprolactone Polyol: Component (C)

This includes a compound obtained by ring-cleavage polymerization of ε-caprolactone. Above all, preferred are those having a number-average molecular weight of 400 to 2000, more preferably 500 to 1500, most preferably 600 to 1200. A compound having (two) hydroxy groups (in the molecule) at both terminals alone of the molecule corresponds to the component (C11) that constitutes the urethane prepolymer (B1), and a compound having three or more hydroxy groups in the molecule corresponds to the component (CB).

These polycaprolactone polyols are available as chemical reagents or industrially, and examples of commercial products thereof include “Placcel (registered trademark)” series by Daicel Corporation.

### Polycarbonate Polyol: Component (C)

This includes a compound obtained by phosgenation of at least one low-molecular polyol, and a compound obtained by interesterification with ethylene carbonate, diethyl carbonate or diphenyl carbonate. Above all, preferred are those having a number-average molecular weight of 400 to 2000, more preferably 500 to 1500, most preferably 600 to 1200. A compound having (two) hydroxy groups (in the molecule) at both terminals alone of the molecule corresponds to the component (C11) that constitutes the urethane prepolymer (B1), and a compound having three or more hydroxy groups in the molecule corresponds to the component (CB).

Here, the low-molecular polyol includes low-molecular polyols such as ethylene glycol, 1,2-propanediol, 1,3-propanediol, 2-methyl-1,3-propanediol, 1,2-butanediol, 1,3-butanediol, 1,4-butanediol, 1,5-pentanediol, 1,6-hexanediol, 1,8-octanediol, 1,9-nonanediol, 1,10-decanediol, 3-methyl-1,5-pentanediol, 2-ethyl-4-butyl-1,3-propanediol, diethylene glycol, dipropylene glycol, neopentyl glycol, cyclohexane-1,4-diol, cyclohexane-1,4-dimethanol, dimer acid diol, bisphenol A ethylene oxide or propylene oxide adduct, bis(β-hydroxyethyl)benzene, xylylene glycol, glycerin, trimethylolpropane, and pentaerythritol.

### Polyacryl Polyol: Component (C)

This includes a polyol compound obtained by polymerization of a (meth)acrylate or a vinyl monomer. A compound having (two) hydroxy groups (in the molecule) at both terminals alone of the molecule corresponds to the component (C11) that constitutes the urethane prepolymer (B1), and a compound having three or more hydroxy groups in the molecule corresponds to the component (CB).

### Castor Oil Polyol: Component (C)

The castor oil polyol includes a polyol compound produced from a starting material of castor oil, a type of natural oils and fats. A compound having (two) hydroxy groups (in the molecule) at both terminals alone of the molecule corresponds to the component (C11) that constitutes the urethane prepolymer (B1), and a compound having three or more hydroxy groups in the molecule corresponds to the component (CB).

These castor oil polyols are available as chemical reagents or industrially, and examples of commercial products thereof include “URIC (registered trademark)” series by Itoh Oil Chemicals Co., Ltd.

### ((C) Compound Having at Least Two Thiol Groups: Component (C))

As preferred examples of the thiol group-having compound among the component (C), usable are those described in WO2015/068798A. Among them, the following are especially preferred.

Tetraethylene glycol bis(3-mercaptopropionate), 1,4-butanediol bis(3-mercaptopropionate), 1,6-hexanediol bis(3-mercaptopropionate), and 1,4-bis(mercaptopropylthiomethyl)benzene (corresponding to the component (C11) constituting the urethane prepolymer (B1)).

Thiols such as trimethylolpropane tris(3-mercaptopropionate), pentaerythritol tetrakis(3-mercaptopropionate), dipentaerythritol hexakis(3-mercaptopropionate), 1,2-bis[(2-mercaptoethyl)thio]-3-mercaptopropane, 2,2-bis(mercaptomethyl)-1,4-butanediol, 2,5-bis(mercaptomethyl)-1,4-dithiane, 4-mercaptomethyl-1,8-dimercapto-3,6-dithiaoctane, 1,1,1,1-tetrakis(mercaptomethyl)methane, 1,1,3,3-tetrakis(mercaptomethylthio)propane, 1,1,2,2-tetrakis(mercaptomethylthio)ethane, 4,6-bis(mercaptomethylthio)-1,3-dithiane, and tris-{(3-meraptopropionyloxy)ethyl}-isocyanurate (corresponding to the component (CB)).

OH/SH Polymerizable Group-Containing Monomer: Component (C)

The compound having both a hydroxy group and a thiol group among the component (C) includes the following.

2-Mercaptoethanol, 1-hydroxy-4-mercaptocyclohexane, 2-mercaptohydroquinone, 4-mercaptophenol, 1-hydroxyethylthio mercaptoethylthiobenzene, 4-hydroxy-4′-mercaptodiphenyl sulfone, 2-(2-mercaptoethylthio)ethanol, dihydroxydiethyl sulfide mono(3-mercaptopropionate), and dimercaptoethane mono(salicylate) (corresponding to the component (C11) constituting the urethane prepolymer (B1)).

A polyfunctional OH/SH polymerizable group-containing monomer (corresponding to the component (CB)), such as 3-mercapto-1,2-propanediol, glycerin di(mercaptoacetate), 2,4-dimercaptophenol, 1,3-dimercapto-2-propanol, 2,3-dimercapto-1-propanol, 1,2-dimercapto-1,3-butanediol, pentaerythritol tris(3-mercaptopropionate), pentaerythritol mono(3-mercaptopropionate), pentaerythritol bis(3-mercaptopropionate), pentaerythritol tris(thioglycolate), pentaerythritol pentakis(3-mercaptopropionate), hydroxymethyl-tris(mercaptoethylthiomethyl)methane, and hydroxyethylthiomethyl-tris(mercaptoethylthio)methane.

Polyrotaxane Having a Hydroxy Group and/or a Thiol Group: Component (C)

Polyrotaxane is a molecular complex having such a structure that a linear axial molecule runs through the rings of plural cyclic molecules, in which a bulky group bonds to both ends of the axial molecule to prevent the cyclic molecules from falling out of the axial molecule owing to steric hindrance, and is called a supramolecule. The polyrotaxane usable as the component (C) in the present invention is a polyrotaxane having a hydroxy group and/or a thiol group polymerizable with an isocyanate group, and those having three or more groups of a hydroxy group and/or a thiol group correspond to the component (CB). The polyrotaxane having a hydroxy group and/or a thiol group for use as the component (C) in the present invention is not specifically limited, for which, for example, polyrotaxanes described in WO2018/092826 are exemplified.

Preferred examples of the component (CB) for use in the present invention include glycerin, trimethylolethane, trimethylolpropane, ditrimethylolpropane, trimethylolpropane tripolyoxyethylene ether (TMP-30 by Nippon Nyukazai Co., Ltd.), polyester polyol having three or more hydroxy groups, polyether polyol having three or more hydroxy groups, castor oil polyol having three or more hydroxy groups, and polyrotaxane having a hydroxy group and/or a thiol group. More preferred is a polyrotaxane having three or more groups of a hydroxy group and/or a thiol group.

### <Blending Ratio of Polymerizable Composition>

In the polymerizable composition for use in the present invention, the blending ratio of the component (B) and the component (C) is not specifically limited. In particular, for exhibiting excellent effects, it is preferable that, when the total of the iso(thio)cyanate groups of the component (B) in the polymerizable composition is 1 mol, the total molar number of the active hydrogen groups in the component (C) is 0.8 to 2.0 mols. When the amount of the iso(thio)cyanate groups is too much or too small, the resultant polyurethane(urea) resin may poorly cure or the wear resistance thereof may worsen. For obtaining a polyurethane(urea) resin having a further better curing state in a more uniform condition and having much more excellent wear resistance, preferably, the total molar number of the active hydrogen atoms is 0.85 to 1.75 mols when the total of the iso(thio)cyanate groups is 1 mol, even more preferably 0.9 to 1.5 mols. In calculating the total molar number of the active hydrogen groups of the component (C), when a compound having two or more amino groups (CA) is used, the molar number of the active hydrogens of the compound having two or more amino groups is equal to the molar number of the amino groups.

In order that the polymerizable composition in the present invention can express excellent wear resistance characteristics when cured, preferably, the component (C) contains the component (CA), as mentioned above, and more preferably contains the component (CA) and the component (CB).

Namely, the polymerizable composition for use in the present invention contains the component (B) and the component (CA), even more preferably the component (B), the component (CA) and the component (CB).

For example, in the case where the polymerizable composition contains the component (B), the component (CA) and the component (CB), the blending ratio of the components is preferably such that, relative to 100 parts by mass of the total of the component (B), the component (CA) and the component (CB), the component (B) is 60 to 95 parts by mass, the component (CA) is 2 to 20 parts by mass, and the component (CB) is 1 to 30 parts by mass, more preferably the component (B) is 70 to 85 parts by mass, the component (CA) is 2 to 15 parts by mass and the component (CB) is 3 to 25 parts by mass.

### <Other Formulation Ingredients to be Blended in the Polymerizable Composition>

For the polymerizable composition for use in the present invention, a urethane or urea reaction catalyst can be used for smoothly promoting the polymerization. Specific examples of the urethane or urea reaction catalyst favorably usable in the present invention are described in WO2015/068798A.

One alone or two or more kinds of these urethane or urea reaction catalysts can be used either singly or as combined. The amount to be used of the catalyst may be a so-called catalytic amount, and is, for example, within a range of 0.001 to 10 parts by mass per 100 parts by mass of the total of the component (B) and the component (C), especially 0.01 to 5 parts by mass.

In addition, various known ingredients can be used in the polymerizable composition for use in the present invention, within a range not detracting from the advantageous effects of the present invention. For example, abrasive grains, an antioxidant, a UV absorbent, an IR absorbent, a discoloration inhibitor, a fluorescent dye, a dye, a photochromic compound, a pigment, a fragrance material, a surfactant, a flame retardant, a plasticizer, a filler, an antistatic agent, a foam stabilizer, a solvent, a leveling agent and other additives can be added. One alone or two or more kinds of these additives can be used either singly or as combined.

The polymerization method for use in the present invention is not specifically limited, and a known method may be employed. For example, the conditions described in WO2015/068798A, WO2016/143910A, and WO2018/092826A may be employed. Specifically, a dry method such as a one pot method or a prepolymer method, and a wet method using a solvent can be used. Among these, a dry method is preferred.

The CMP polishing pad of the present invention is not specifically limited so far as it contains the hollow microballoons of the present invention and the above-mentioned polyurethane(urea) resin. The production method for it is not also specifically limited, but especially preferred is a method of uniformly mixing and dispersing the hollow microballoons of the present invention in the polymerizable composition containing the component (B) and the component (C), following by polymerizing the composition.

Regarding the blending amount of the hollow microballoons of the present invention in the polyurethane(urea) resin in the above-mentioned method, it is preferable that the amount of the hollow microballoons of the present invention is 0.1 to 20 parts by mass per 100 parts by mass of the total amount of the component (B) and the component (C), more preferably 0.2 to 15 parts by mass, even more preferably 0.5 to 10 parts by mass. Within the range, excellent polishing characteristics can be expressed.

The content of the hollow microballoons in the CMP polishing pad of the present invention is preferably 0.1 to 20 parts by mass relative to 100 parts by mass of the polyurethane(urea) resin, more preferably 0.2 to 15 parts by mass, even more preferably 0.5 to 10 parts by mass. Within the range, excellent polishing characteristics can be expressed.

The CMP polishing pad of the present invention may use a foamed polyurethane(urea) resin. The density of the foamed polyurethane(urea) resin is preferably 0.40 to 0.95 g/cm³. For foaming the polyurethane(urea) resin, a known method is employable with no limitation. For example, in a foaming method with a foaming agent in which water is added, after water is reacted with an iso(thio)cyanate group, carbon dioxide and an amino group are formed. The carbon dioxide acts as a foaming gas, and the amino group is further reacted with an iso(thio)cyanate group to form a urea bond and/or a thiourea bond.

The CMP polishing pad of the present invention can have any desired hardness. The hardness in the present invention can be measured according to a Shore method, and for example, can be measured according to JIS standard (hardness test) K6253. In the present invention, the Shore hardness of the CMP polishing pad is preferably 30A to 70D, more preferably 40A to 60D. (Here, “A” indicates a hardness by a Shore “A” scale, and “D” indicates a hardness by a Shore “D” scale.) Specifically, for example, 30A to 70D means that the Shore A hardness is 30 or more and the Shore D hardness is 70 or less.

The hardness can be controlled to any hardness, as needed, by varying the blending formulation and the blending amount of the constituent ingredients.

Further, the CMP polishing pad of the present invention preferably has a compression ratio falling within the following range, for flatness control of polished substances. The compression ratio can be measured according to a method of JIS L 1096. The compression ratio is preferably 0.5% to 50%. Within the range, polished substances can express excellent flatness.

The wear resistance of the CMP polishing pad of the present invention is preferably 60 mg or less in a Tabor wear test, more preferably 50 mg or less. A small Tabor wear loss means that the CMP polishing pad can express excellent wear resistance. Regarding the detailed implementation approach for the Tabor wear test, reference may be made to the description given hereinunder in the section of Examples.

The CMP polishing pad of the present invention may be composed of plural layers. In that case, the polyurethane(urea) resin can be used in at least any layer. For example, in the case where the CMP polishing pad is composed of two layers, this has a two-layer configuration of a polishing layer having a polishing surface to be in contact with the substance to be polished in polishing it (this is also referred to as a first layer), and a base layer that is in contact with the first layer on the surface opposite to the polishing surface of the first layer (this is also referred to as a second layer). In that case, the second layer may be made to differ from the first layer in the hardness and the elastic modulus to control the characteristics of the CMP polishing pad. In such a case, preferably, the hardness of the base layer is smaller than that of the polishing layer. In the present invention, it is favorable that the polyurethane(urea) resin is used as the polishing layer, and further, the polyurethane(urea) resin may also be used as the base layer.

For the polyurethane(urea) resin, the polymerizable composition may be made to contain abrasive grains and polymerized to give an abrasive grains-fixed polyurethane(urea) resin. Examples of the abrasive grains include grains of a material selected from cerium oxide, silicon oxide, alumina, silicon carbide, zirconia, iron oxide, manganese dioxide, titanium oxide and diamond, or grains of at least two of these materials. The method of incorporating these abrasive grains is not specifically limited. For example, these abrasive grains are dispersed in the polymerizable composition and then the polymerizable composition is polymerized.

In the present invention, the profile of the CMP polishing pad is not specifically limited. For example, a grooved structure may be formed on the surface. The grooved structure of the CMP polishing pad is preferably so configured as to be able to hold and renew a slurry therein. Specifically, the structure includes an X (stripe) groove, an XY lattice groove, a concentric groove, a through-hole, a non-through-hole, a polygonal groove, a columnar groove, a spiral groove, an eccentric groove, a radial groove and a combination of these grooves.

The method for forming the grooved structure of the CMP polishing pad is not specifically limited. Examples of the method include a mechanically cutting method using a tool such as a byte having a predetermined size, a method of casting a resin into a mold having a predetermined surface profile and curing it therein, a method of pressing a resin with a pressing board having a predetermined surface profile, a method of photolithography for forming the structure, a method using a printing method for forming the structure, and a formation method with a laser ray such as a carbon dioxide laser.

### EXAMPLES

Next, the present invention is described in detail with reference to Examples and Comparative Examples, but the present invention is not limited to these Examples. In the following Examples and Comparative Examples, the constituent components and evaluation methods are as mentioned below.

### [Constituent Components]

### (a) Component: Organic Solvent

Tol: toluene

### (A) Component: Emulsifier

Polyethylene-maleic anhydride (average molecular weight 100,000 to 500,000)

PVA: completely saponified polyvinyl alcohol having an average polymerization degree of about 500

### (Polymerizable Monomer)

Melamine-formaldehyde prepolymer compound

Nikaresin S-260 (by Nippon Carbide Industries Co., Inc.): water-soluble methylolmelamine (melamine-formaldehyde precondensation product)

Urea

Formaldehyde

Isophthalic acid dichloride

P-phenylenediamine

### (B) Component

Pre-1: Terminal Isocyanate Urethane Prepolymer Having an Isocyanate Equivalent of 905

### (Production Example for Pre-1)

In a flask equipped with a nitrogen-introducing duct, a thermometer and a stirrer, 50 g of 2,4-tolylene diisocyanate, 90 g of polyoxytetramethylene glycol (number-average molecular weight: 1,000) and 12 g of diethylene glycol were reacted in a nitrogen atmosphere at 80° C. for 6 hours to give a terminal isocyanate urethane prepolymer (Pre-1) having an isocyanate equivalent of 905.

Pre-2: Urethane Prepolymer Having an Isocyanate Group at Both Terminals and Having an Isocyanate Equivalent of 460

### (Production Example for Pre-2)

In a flask equipped with a nitrogen-introducing duct, a thermometer and a stirrer, 1000 g of 2,4-tolylene diisocyanate, and 1100 g of polypropylene glycol (number-average molecular weight: 500) were reacted in a nitrogen atmosphere at 80° C. for 4 hours, and then 120 g of diethylene glycol was added and reacted at 80° C. for 5 hours to give a terminal isocyanate urethane prepolymer (Pre-2) having an iso(thio)cyanate equivalent of 460.

### (C) Component, MOCA: 4,4′-Methylenebis(o-Chloroaniline) (Component (CA))

Heart Cure 30: Dimethylthiotoluenediamine by Kumiai Chemical Industry Co., Ltd. (component CA)

TMP: Trimethylolpropane (component (CB))

Poly #10: POLYCASTOR #10 by Itoh Oil Chemicals Co., Ltd., castor oil polyol in which the active hydrogen group is 2.8 mmol/g by weight and the hydroxy group is 5-to 6-functional (component (CB)).

RX-1: Polyrotaxane monomer having a hydroxy group in the side chains and having a weight-average molecular weight of 165,000, in which the molecular weight of the side chains is about 350 on average (component (CB))

RX-1 was produced as follows.

### (1-1) Preparation of PEG-COOH:

As a polymer for an axial molecule, a linear polyethylene glycol (PEG) having a molecular weight of 10,000 was prepared. PEG: 10 g, 2,2,6,6-tetramethyl-1-piperidinyloxy radical: 100 mg, and sodium bromide: 1 g were dissolved in 100 mL of water. 5 mL of an aqueous sodium hypochlorite solution (effective chlorine concentration 5%) was added to the solution, and stirred at room temperature for 10 minutes. Subsequently, 5 mL of ethanol was added to terminate the reaction. This was extracted with 50 mL of methylene chloride, then methylene chloride was evaporated away, and the residue was dissolved in 250 mL of ethanol for reprecipitation for 12 hours at a temperature of −4° C. to give PEG-COOH, which was then collected and dried.

### (1-2) Preparation of Polyrotaxane:

3 g of PEG-COOH prepared in the above and 12 g of α-cyclodextrin (α-CD) were separately dissolved in 50 mL of water at 70° C., and the resultant solutions were mixed by fully shaking them. Next, the resultant mixed solution was reprecipitated at a temperature of 4° C. for 12 hours, and the precipitated encapsulation complex was lyophilized and collected. Subsequently, 0.13 g of adamantane amine was dissolved in 50 ml of dimethylformamide (DMF) at room temperature, and then the above encapsulation complex was added thereto and rapidly mixed by fully shaking them. Subsequently, 0.38 g of a reagent benzotriazol-1-yl-oxy-tris(dimethylamino)phosphonium hexafluorophosphate was dissolved in 5 mL of DMF and the resultant solution was added to the above, and mixed by fully shaking them. Further, 0.14 ml of diiospropylethylamine was dissolved in 5 mL of DMF, and the resultant solution was added thereto and mixed by fully shaking them to prepare a slurry reagent.

The slurry reagent prepared in the above was statically kept at 4° C. for 12 hours. Subsequently, 50 ml of a mixed solvent DMF/methanol (volume ratio 1/1) was added, mixed and centrifuged to remove the supernatant. Further, this was washed with the above mixed solvent DMF/methanol, washed with methanol, and centrifuged to give a precipitate. The resultant precipitate was dried in vacuum and dissolved in 50 mL of dimethyl sulfoxide (DMSO), and the resultant transparent solution was dropwise added to 700 mL of water to precipitate polyrotaxane. The precipitated polyrotaxane was collected by centrifugal separation, and dried in vacuum. Further, this was dissolved in DMSO, precipitated in water, collected and dried to give a pure polyrotaxane. At that time, the encapsulation number of α-CD was 0.25.

Here, for the encapsulation number, polyrotaxane was dissolved in DMSO-d₆ and analyzed with a ¹H-NMR measurement device (JNM-LA500, by JEOL Corporation), and the encapsulation number was calculated according to the following method.

Here, X, Y and X/(Y−X) have the following means.

X: Integrated value of 4 to 6 ppm cyclodextrin hydroxy group-derived protons

Y: Integrated value of 3 to 4 ppm cyclodextrin and PEG methylene chain-derived protons

X/(Y−X): Proton ratio of cyclodextrin to PEG

First, X/(Y−X) at a maximum encapsulation number of 1 is theoretically precalculated, and the value is compared with X/(Y−X) calculated from the analytical values of the actual compound to calculate the encapsulation number.

### (1-3) Preparation of Terminal Hydroxy Group-Introduced Side Chain-Modified Polyrotaxane (RX-1)

500 mg of the polyrotaxane purified in the above was dissolved in 50 mL of an aqueous 1 mol/L NaOH solution, 3.83 g (66 mmol) of propylene oxide was added thereto and, in an argon atmosphere, stirred at room temperature for 12 hours. Next, using an aqueous 1 mol/L HCl solution, the above polyrotaxane solution was neutralized to have pH of 7 to 8, dialyzed through a dialysis tube, and lyophilized to give a hydroxypropylated polyrotaxane. The resultant hydroxypropylated polyrotaxane was identified through ¹H-NMR and GPC, and was confirmed to be a hydroxypropylated polyrotaxane having a desired structure.

The modification degree on the hydroxy group of the cyclic molecule by the hydroxypropyl group was 0.5, and the weight-average molecular weight was Mw: 50,000 by GPC measurement.

5 g of the resultant hydroxypropylated polyrotaxane was dissolved in 15 g of ε-caprolactone at 80° C. to prepare a mixed liquid. The mixed liquid was stirred at 110° C. for 1 hour while dry nitrogen was kept blown thereinto, and then 0.16 g of a 50 wt % xylene solution of tin(II) 2-ethylhexanoate was added, and stirred at 130° C. for 6 hours. Subsequently, xylene was added to give a solution of side chains-introduced ε-caprolactone-modified polyrotaxane having a nonvolatile concentration of about 35% by mass.

The ε-caprolactone-modified polyrotaxane xylene solution prepared in the above was dropwise added into hexane, collected and dried to give ε-caprolactone-modified polyrotaxane (RX-1).

### [Evaluation Methods]

### (1) Density:

The density (g/cm³) was measured with (DSG-1) by Toyo Seiki Seisaku-sho, Ltd.

### (2) Polishing Rate:

The polishing rate was measured by polishing under the following conditions. The polishing rate is an average value of the data of ten 2-inch sapphire wafer samples.

CMP polishing pad: Pad having a size of 500 mmφ and a thickness of 1 mm, with concentric grooves formed on the surface.

Slurry: FUJIMI Compol 80, undiluted liquid

Pressure: 4 psi

Rotation number: 45 rpm

Time: 1 hr

### (3) Surface Roughness (Ra):

The surface of each 10 2-inch sapphire wafer samples polished under the conditions in the above (2) was observed with a nanosearch microscope SFT-4500 (by Shimadzu Corporation) to measure the surface roughness (Ra) thereof. The surface roughness is an average value of the data of the ten 2-inch sapphire wafer samples.

### (4) Ash Content:

Hollow microballoons were fired at a temperature of 600° C., and the ash content is a proportion of the mass of the combustion residue and the mass of the hollow microballoons before firing.

### (5) Scratch Resistance:

Presence or absence of scratches on the 2-inch sapphire wafers polished under the condition described in the above (2) was checked. The samples were evaluated under the following criteria.

1: In observation with a laser microscope, all the ten wafers had no defects.
2: In observation with a laser microscope, one or two of the ten wafers had defects.
3: In observation with a laser microscope, 3 to 5 of the ten wafers had defects.

### (6) D Hardness:

According to the JIS standard (hardness test) K6253, the Shore D hardness was measured with a durometer by Kobunshi Keiki Co., Ltd. The samples were piled up to have a thickness of 6 mm in all, and then measured. Those having a relatively low hardness was measured in terms of Shore A hardness, and those having a relatively high hardness was in terms of Shore D hardness.

### (7) Wear Resistance:

Using an apparatus of 5130 Model by Tabor Electronics Ltd., a Tabor wear was measured. The load was 1 kg, the rotation speed was 60 rpm, the rotation number was 1000 rotations, and the wear ring was H-18. In the Tabor wear test, a wear loss was measured.

### Example 1

A component (a) was prepared from 100 parts by mass of toluene alone. Next, 10 parts by mass of polyethylene-maleic anhydride was mixed in 200 parts by mass of water, and the mixed liquid was controlled to have a pH of 4 with an aqueous 10% sodium hydroxide solution to prepare a component (A). Next, the prepared component (a) and component (A) were mixed, and stirred under the condition of 2,000 rpm×10 minutes at 25° C. using a high-speed shear disperser to give an O/W emulsion. 9 parts by mass of a melamine-formaldehyde prepolymer compound, Nikaresin S-260 was added to the prepared O/W emulsion, and stirred at 65° C. for 24 hours, then cooled to 30° C., and was controlled to have a pH of 7.5 with an aqueous ammonia added thereto to give a dispersion of microballoons of a resin film of a melamine resin. The microballoons were taken out of the resultant microballoon dispersion by filtration, and dried in vacuum at a temperature of 60° C. for 24 hours to give hollow microballoons. Subsequently, these were classified with a classifier to collect hollow microballoons 1.

The resultant hollow microballoons 1 were formed of a melamine resin, and had an average particle size of 30 μm and a bulk density of 0.13 g/cm³, and no ash content was detected therein.

### Example 2

20 parts by mass of urea, 40.5 parts by mass of an aqueous 37 wt % formaldehyde solution and 2 parts by mass of aqueous 25 wt % ammonia were heated up to 70° C. with stirring. After kept at the temperature for 1 hour, this was cooled down to 30° C. to give an aqueous solution containing a urea formaldehyde prepolymer compound.

Separately, a component (a) was prepared from 100 parts by mass of toluene alone. Next, 10 parts by mass of a sodium salt of a styrene-maleic anhydride copolymer was mixed in 200 parts by mass of water, and the mixed liquid was controlled to have a pH of 4.5 with an aqueous 10% sodium hydroxide solution to prepare a component (A). Next, the prepared component (a) and component (A) were mixed, and stirred under the condition of 2,000 rpm×10 minutes at 25° C. using a high-speed shear disperser to give an O/W emulsion. 45 parts by mass of the aqueous solution containing a urea formaldehyde prepolymer compound prepared in the above was added to the prepared O/W emulsion, and stirred at 65° C. for 24 hours, then cooled to 30° C., and was controlled to have a pH of 7.5 with an aqueous ammonia added thereto to give a dispersion of microballoons of a urea resin. The microballoons were taken out of the resultant microballoon dispersion by filtration, dried in vacuum at a temperature of 60° C. for 24 hours, and then classified with a classifier to collect hollow microballoons 4.

The resultant hollow microballoons 4 were formed of a urea resin, and had an average particle size of 20 μm and a bulk density of 0.14 g/cm³, and no ash content was detected therein.

### Example 3

40 parts by mass of isophthalic acid dichloride and 50 parts by mass of toluene were mixed to prepare a component (c). Next, 2.5 parts by mass of PVA and 21 parts by mass of sodium carbonate were added to 50 parts by mass of water to prepare a component (d). Next, the prepared component (c) and component (d) were mixed, and stirred under the condition of 2,000 rpm×10 minutes at 25° C. using a high-speed shear disperser to give an O/W emulsion. A solution prepared by dissolving 32 parts by mass of p-phenylenediamine in 50 parts by mass of water was added to the prepared O/W emulsion, and stirred at 50° C. for 24 hours to give a dispersion of microballoons of a polyamide resin. The microballoons were taken out of the resultant microballoon dispersion by filtration, dried in vacuum at a temperature of 60° C. for 24 hours, and then classified with a classifier to collect hollow microballoons 5.

The resultant hollow microballoons 5 were formed of a polyamide resin, and had an average particle size of 35 μm and a bulk density of 0.15 g/cm³, and no ash content was detected therein.

### Reference Example 1

1 part by mass of Pre-1 was dissolved in 15 parts by mass of toluene to prepare an oily phase component. Next, 10 parts by mass of PVA was dissolved in 150 parts by mass of water to prepare an aqueous phase component. Next, the prepared oily phase component and aqueous phase component were mixed, and stirred under the condition of 2,000 rpm×10 minutes at 25° C. using a high-speed shear disperser to give an O/W emulsion. At 25° C., an aqueous solution of 0.05 parts by mass of ethylenediamine dissolved in 30 parts by mass of water was dropwise added to the prepared O/W emulsion. After the dropwise addition, this was slowly stirred at 25° C. for 60 minutes, and then stirred at 60° C. for 4 hours to give a dispersion of microballoons of a urethane(urea) resin. The microballoons were taken out of the resultant microballoon dispersion by filtration, dried in vacuum at a temperature of 60° C. for 24 hours, and then classified with a classifier to collect hollow microballoons 2.

The resultant hollow microballoons 2 were formed of a urethane(urea) resin, and had an average particle size of 25 μm and a bulk density of 0.10 g/cm³, and no ash content was detected therein.

### Reference Example 2

Hollow microballoons 3 are a commercial product of Microcapsules 920-40 (by Japan Fillite Co., Ltd., hollow microballoons of an acrylonitrile resin whose surfaces were dusted with an inorganic powder), which had an average particle size of 40 μm, a bulk density of 0.03 g/cm³, and an ash content of 1.87 parts by mass.

### Example 4

Using the hollow microballoons 1 produced in the above, a CMP polishing pad was produced.

12 parts by mass of 4,4′-methylenebis(o-chloroaniline) (MOCA) was fully degassed at 120° C. to prepare a liquid B. Separately, 3.3 parts by mass of the hollow microballoons 1 produced in Example 1 were added to 88 parts by mass of Pre-1 produced in Production Example 1 and heated up to 70° C., and stirred with a rotation/revolution stirrer to give a uniform liquid A.

Here, for stability evaluation of hollow microballoons, a polyurethane(urea) resin for CMP polishing pad was prepared according to the following two methods.

### (Production Method 1)

After prepared, the liquid A was kept warmed at 70° C. for 30 minutes, and the liquid B kept at 120° C. was added thereto and stirred with a rotation/revolution stirrer to give a uniform polymerizable composition. The polymerizable composition was cast into a mold, and cured therein at 100° C. for 15 hours to give a polyurethane(urea) resin.

### (Production Method 2)

After prepared, the liquid A was kept warmed at 70° C. for 6 hours, and the liquid B kept at 120° C. was added thereto and stirred with a rotation/revolution stirrer to give a uniform polymerizable composition. The polymerizable composition was cast into a mold, and cured therein at 100° C. for 15 hours to give a polyurethane(urea) resin.

The resultant polyurethane(urea) resin was sliced to give CMP polishing pad of a polyurethane(urea) resin each having a diameter of 500 mmφ and a thickness of 1 mm and having concentric grooves formed on the surface. Depending on the difference in the warming time of the liquid A, the physical properties of the CMP polishing pad produced here were compared.

The CMP polishing pad of a polyurethane(urea) resin produced in the above had no difference in that in (production method 1), the density was 0.85 g/cm³, the polishing rate was 2.1 μm/hr and the surface roughness of the polished wafer of a substance to be polished was 0.25 nm, and in (production method 2), the density was 0.85 g/cm³, the polishing rate was 2.1 μm/hr and the surface roughness of the polished wafer of a substance to be polished was 0.25 nm.

### Example 5

A CMP polishing pad of a polyurethane(urea) resin was produced and evaluated in the same manner as in Example 1, except that 24 parts by mass of RX-1 and 5 parts by mass of 4,4′-methylenebis(o-chloroaniline) (MOCA) were mixed at 120° C. to give a uniform solution, and then degassed to be a liquid B, and 71 parts by mass of Pre-1 was used. The results are shown in Table 1.

### Examples 6 to 13, Comparative Examples 1, 2

CMP polishing pad of a polyurethane(urea) resin were produced and evaluated in the same manner as in Example 1, except that the compositions shown in Table 1 were used. The results are shown in Table 1.

TABLE 1

| | Hollow Microballoons | | Polyurethane(urea) Resin Composition (part by mass) | | | | | | | | | |
|---|---|---|---|---|---|---|---|---|---|---|---|---|
| | (part by mass) | | Component (B) | | | Component (CA) | | | | Component (CB) | | |
| Example 4 | Hollow Microballoons 1 | | Pre-1 | | | MOCA | | | | — | | |
| | (3.3) | | (88) | | | (12) | | | | | | |
| Example 5 | Hollow Microballoons 1 | | Pre-1 | | | MOCA | | | | RX-1 | | |
| | (3.3) | | (71) | | | (5) | | | | (24) | | |
| Example 6 | Hollow Microballoons 1 | | Pre-1 | | | MOCA | | | | TMP | | |
| | (3.3) | | (91) | | | (7) | | | | (2) | | |
| Example 7 | Hollow Microballoons 1 | | Pre-2 | | | MOCA | | | | TMP | | |
| | (3.3) | | (84) | | | (12) | | | | (4) | | |
| Example 8 | Hollow Microballoons 1 | | Pre-1 | | | Heart Cure 30 | | | | RX-1 | | |
| | (3.3) | | (72) | | | (4) | | | | (24) | | |
| Example 9 | Hollow Microballoons 1 | | Pre-2 | | | MOCA | | | | — | | |
| | (3.3) | | (78) | | | (22) | | | | | | |
| Example 10 | Hollow Microballoons 1 | | Pre-1 | | | MOCA | | | | poly# 10 | | |
| | (3.3) | | (79) | | | (6) | | | | (15) | | |
| Example 11 | Hollow Microballoons 1 | | Pre-1 | | | Heart Cure 30 | | | | RX-1 | | |
| | (3.3) | | (66) | | | (2) | | | | (32) | | |
| Example 12 | Hollow Microballoons 4 | | Pre-1 | | | MOCA | | | | — | | |
| | (3.3) | | (88) | | | (12) | | | | | | |
| Example 13 | Hollow Microballoons 5 | | Pre-1 | | | MOCA | | | | — | | |
| | (3.3) | | (88) | | | (12) | | | | | | |
| Comparative | Hollow Microballoons 2 | | Pre-1 | | | MOCA | | | | — | | |
| Example 1 | (3.3) | | (88) | | | (12) | | | | | | |
| Comparative | Hollow Microballoons 3 | | Pre-1 | | | MOCA | | | | — | | |
| Example 2 | (1.0) | | (88) | | | (12) | | | | | | |
| | Production Method 1 | | | | | | Production Method 2 | | | | | |
| | | | Wafer | | | | | | Wafer | | | |
| | | Polishing | Surface | Scratch | D | Wear Re- | | Polishing | Surface | Scratch | D | Wear |
| | Density | Rate | Roughness | Re- | Hard- | sistance | Density | Rate | Roughness | Re- | Hard- | Resistance |
| | (g/cm³) | (μm/hr) | Ra (nm) | sistance | ness | (mg) | (g/cm³) | (μm/hr) | Ra (nm) | sistance | ness | (mg) |
| Example 4 | 0.85 | 2.1 | 0.25 | 1 | 60 | 53 | 0.85 | 2.1 | 0.25 | 1 | 60 | 53 |
| Example 5 | 0.85 | 3.5 | 0.23 | 1 | 25 | 19 | 0.85 | 3.5 | 0.23 | 1 | 25 | 19 |
| Example 6 | 0.85 | 2.3 | 0.25 | 1 | 40 | 38 | 0.85 | 2.3 | 0.25 | 1 | 40 | 38 |
| Example 7 | 0.85 | 2.4 | 0.26 | 1 | 45 | 40 | 0.85 | 2.4 | 0.26 | 1 | 45 | 40 |
| Example 8 | 0.85 | 3.3 | 0.23 | 1 | 27 | 24 | 0.85 | 3.3 | 0.23 | 1 | 27 | 24 |
| Example 9 | 0.85 | 2.1 | 0.27 | 1 | 67 | 55 | 0.85 | 2.1 | 0.27 | 1 | 67 | 55 |
| Example 10 | 0.85 | 3.2 | 0.24 | 1 | 24 | 29 | 0.85 | 3.2 | 0.24 | 1 | 24 | 29 |
| Example 11 | 0.85 | 2.8 | 0.23 | 1 | 22 | 20 | 0.85 | 2.8 | 0.23 | 1 | 22 | 20 |
| Example 12 | 0.85 | 2.0 | 0.25 | 1 | 60 | 56 | 0.85 | 2.0 | 0.25 | 1 | 60 | 56 |
| Example 13 | 0.85 | 2.0 | 0.25 | 1 | 59 | 54 | 0.88 | 1.8 | 0.25 | 1 | 60 | 56 |
| Comparative | 0.80 | 2.0 | 0.25 | 1 | 59 | 50 | 1.00 | 0.8 | 0.27 | 1 | 60 | 51 |
| Example 1 | | | | | | | | | | | | |
| Comparative | 0.80 | 1.0 | 0.32 | 3 | 60 | 61 | 0.80 | 1.0 | 0.32 | 3 | 60 | 63 |
| Example 2 | | | | | | | | | | | | |

As known from the results in Table 1, the hollow microballoons of the present invention can provide CMP polishing pad having an excellent polishing rate and capable of more smoothly polishing the substances to be polished, wafers, and as compared with hollow microballoons formed of a polyurethane(urea) resin, the hollow microballoons of the present invention can stably produce CMP polishing pad without worsening polishing characteristics, even though stored as blended with a polymerizable monomer for a long period of time.

Further, by using a polyurethane(urea) resin that uses, as a compound having an active hydrogen group with an active hydrogen polymerizable with an isocyanate group, a polyrotaxane having an active hydrogen group with an active hydrogen polymerizable with an isocyanate group, as a substrate for CMP polishing pad, further excellent polishing characteristics can be expressed.

1. Hollow microballoons for CMP polishing pad, comprising at least one resin selected from the group consisting of a melamine resin, a urea resin, and an amide resin and having an average particle size of 1 to 100 μm.

2. The hollow microballoons for CMP polishing pad according to claim 1, wherein a bulk density of the hollow microballoons is 0.01 to 0.6 g/cm³.

3. The hollow microballoons for CMP polishing pad according to claim 1, wherein an ash content of the hollow microballoons is 0.5 parts by mass or less relative to 100 parts by mass of the hollow microballoons.

4. A CMP polishing pad containing the hollow microballoons for CMP polishing pad according to claim 1 and a polyurethane(urea) resin.

5. The CMP polishing pad according to claim 4, having a Shore hardness of 30A to 70D.

6. The CMP polishing pad according to claim 4, wherein the polyurethane(urea)resin comprises a resin produced by polymerizing a polymerizable composition containing (B) a polyfunctional isocyanate compound and (CA) a compound having two or more amino groups.

7. The CMP polishing pad according to claim 4, wherein the polyurethane(urea) resin comprises a resin produced by polymerizing a polymerizable composition containing (B) a polyfunctional isocyanate compound, (CA) a compound having two or more amino groups and (CB) a compound having three or more groups of a hydroxy group and/or a thiol group.

8. The CMP polishing pad according to claim 7, wherein a blending ratio of the (B) polyfunctional isocyanate compound, the (CA) compound having two or more amino groups, and the (CB) compound having three or more groups of a hydroxy group and/or a thiol group is 60 to 95 parts by mass, 2 to 20 parts by mass, and 1 to 30 parts by mass, respectively, relative to 100 parts by mass of the total of a component (B), a component (CA), and a component (CB).

9. The CMP polishing pad according to claim 7, wherein a (CB) compound having three or more groups of a hydroxy group and/or a thiol group comprises a polyrotaxane having three or more groups of a hydroxy group and/or a thiol group.
